(19) United States
(12) Patent Application Publication
(10) Pub. No.: US 2025/0280674 A1
(43) Pub. Date: Sep. 4, 2025

(54) LIGHT EMITTING DISPLAY APPARATUS

(71) Applicant: LG Display Co., Ltd., Seoul (KR)

(72) Inventors: Sunghee PARK, Paju-si (KR); JaeHee PARK, Paju-si (KR); JongSung KIM, Paju-si (KR); Hoiyong KWON, Paju-si (KR); Youngwan KIM, Paju-si (KR)

(21) Appl. No.: 18/931,928

(22) Filed: Oct. 30, 2024

(30) Foreign Application Priority Data
Feb. 29, 2024 (KR) 10-2024-0030288
Aug. 14, 2024 (KR) 10-2024-0109346

(51) Int. Cl. H10K 59/131; G09G 3/3225

(52) U.S. Cl. CPC H10K 59/131; G09G 3/3225; G09G 2330/12

(57) ABSTRACT

Disclosed is a light emitting display apparatus comprising a light emitting element including a pixel electrode, an emission layer, and a common electrode, a pixel circuit connected to the pixel electrode, a first common power line connected to the common electrode and configured to be applied with a first common power voltage, and a second common power line connected to the common electrode and configured to be applied with a second common power voltage, wherein the pixel electrode includes a first divided pixel electrode and a second divided pixel electrode which are divided from each other, and the first divided pixel electrode and the second divided pixel electrode have different electrical distances with respect to the first common power line and the second common power line.

### CROSS-REFERENCE TO RELATED APPLICATIONS

This application claims the benefit of and priority to Republic of Korea Patent Application No. 10-2024-0030288 filed on Feb. 29, 2024, and No. 10-2024-0109346 filed on Aug. 14, 2024, both of which are incorporated herein by reference as if fully set forth herein for all purposes.

### BACKGROUND

### Technical Field

The present disclosure relates to a light emitting display apparatus.

### Description of the Related Art

With the development of information society, the demand for a display apparatus for displaying an image is increasing in various forms. Accordingly, display apparatuses such as a liquid crystal display LCD apparatus, an organic light emitting display OLED apparatus, a micro light emitting diode LED display apparatus, a quantum dot display QD apparatus, and the like are used.

Among the display apparatuses, the organic light emitting display apparatus is a self-luminous type. In the organic light emitting display apparatus, hole and electron are injected into an emission layer from an anode electrode for hole injection and a cathode electrode for electron injection, and the injected hole and electron are bonded to each other. Herein, when the bonded hole and electron exciton fall from the excited state to the ground state, the organic light emitting display apparatus may emit light and display an image.

### BRIEF SUMMARY

The organic light emitting display apparatus has a limitation in that dark spots may occur due to the generation of foreign substances between the anode electrode and the cathode electrode in a process of forming the cathode electrode of light emitting element through a sputtering process.

The present disclosure provides a light emitting display apparatus having a repair structure for a short defect between an anode electrode and a cathode electrode.

The present disclosure provides a light emitting display apparatus capable of automatically detecting a semi-dark repair target of a divided subpixel by applying a differential power voltage to two divided common power lines.

The present disclosure provides a light emitting display apparatus having a power pad contact structure capable of reducing a resistance deviation in each of two divided common power lines and reducing heat in a power pad portion.

The present disclosure provides a light emitting display apparatus capable of improving detection reliability of semi-dark repair target of a subpixel divided through a power pad contact structure for compensating a resistance deviation in each of two divided common power lines.

The technical features of the present disclosure are not limited to those aforesaid, but other technical features not described herein will be clearly understood by those skilled in the art from descriptions below.

In accordance with an aspect of the present disclosure, a light emitting display apparatus comprises a light emitting element including a pixel electrode, an emission layer, and a common electrode, a pixel circuit connected to the pixel electrode, a first common power line connected to the common electrode and applied with a first common power voltage, and a second common power line connected to the common electrode and applied with a second common power voltage, wherein the pixel electrode includes a first divided pixel electrode and a second divided pixel electrode which are divided from each other, and the first divided pixel electrode and the second divided pixel electrode have different electrical distances with respect to the first common power line and the second common power line.

According to one or more embodiments of the present disclosure, it is possible to provide the light emitting display apparatus having the repair structure for the short defect between the anode electrode and the cathode electrode.

According to one or more embodiments of the present disclosure, it is possible to provide the light emitting display apparatus capable of automatically detecting the semi-dark repair target of subpixel divided by applying the differential power voltage to the two divided common power lines.

According to one or more embodiments of the present disclosure, it is possible to provide the light emitting display apparatus having the power pad contact structure capable of reducing the resistance deviation in each of two divided common power lines and reducing heat in the power pad portion.

According to one or more embodiments of the present disclosure, it is possible to provide the light emitting display apparatus capable of improving detection reliability of semi-dark repair target of the subpixel divided through the power pad contact structure for compensating the resistance deviation in each of two divided common power lines.

The light emitting display apparatus according to one or more embodiments of the present disclosure may improve the production yield by reducing the tack time of repair process through an accurate detection of the semi-dark repair target and improving the reliability of manufacturing process, whereby it is possible to implement Environment/Social/Governance ESG by reducing the generation of greenhouse gas that may occur due to the manufacturing process.

The effects of the present disclosure are not limited to the aforesaid, but other effects not described herein will be clearly understood by those skilled in the art from descriptions below.

The details of the present disclosure described in technical problem, technical solution, and advantageous effects do not specify essential features of claims, and thus, the scope of claims is not limited by the details described in detailed description of the invention.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain principles of the disclosure.

FIG. 1 illustrates a light emitting display apparatus according to an embodiment of the present disclosure;

FIG. 2 is a block diagram illustrating a light emitting display apparatus according to an embodiment of the present disclosure;

FIG. 3 is a circuit diagram illustrating a subpixel of a light emitting display apparatus according to an embodiment of the present disclosure;

FIG. 4 illustrates a pixel of a light emitting display apparatus according to an embodiment of the present disclosure;

FIGS. 5 to 10 illustrate a region A shown in FIG. 4 according to various embodiments of the present disclosure;

FIG. 11 illustrates a subpixel and a repair detecting part in a light emitting display apparatus according to an embodiment of the present disclosure;

FIG. 12 illustrates a voltage measurement value of a repair detecting part shown in FIG. 11 according to an embodiment of the present disclosure;

FIG. 13 illustrates a subpixel and a repair detecting part of a light emitting display apparatus according to another embodiment of the present disclosure;

FIG. 14 illustrates a voltage measurement value of a repair detecting part shown in FIG. 13 according to another embodiment of the present disclosure;

FIG. 15 illustrates a light emitting display apparatus according to another embodiment of the present disclosure;

FIG. 16 illustrates a region B shown in FIG. 15 according to another embodiment of the present disclosure;

FIG. 17 is a cross-sectional view taken along line I-I′ of FIG. 16 according to another embodiment of the present disclosure;

FIG. 18 is a cross-sectional view taken along line II-II′ of FIG. 16 according to another embodiment of the present disclosure;

FIG. 19 illustrates a region B shown in FIG. 15 according to another embodiment of the present disclosure;

FIG. 20 illustrates a region B shown in FIG. 15 according to another embodiment of the present disclosure;

FIG. 21 is a cross-sectional view taken along line III-III′ of FIG. 20 according to another embodiment of the present disclosure;

FIG. 22 is a cross-sectional view taken along line IV-IV′ of FIG. 20 according to another embodiment of the present disclosure;

FIG. 23 is a cross-sectional view taken along line V-V′ shown in FIG. 20 according to another embodiment of the present disclosure;

FIG. 24 is a cross-sectional view taken along line VI-VI′ of FIG. 20 according to another embodiment of the present disclosure; and

FIG. 25 illustrates a region B shown in FIG. 15 according to another embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction of thereof may be exaggerated for clarity, illustration, and/or convenience.

### DETAILED DESCRIPTION

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete, to assist those skilled in the art to understand the inventive concepts without limiting the protected scope of the present disclosure.

Shapes (e.g., sizes, lengths, widths, heights, thicknesses, locations, radii, diameters, and areas), sizes, ratios, angles, numbers, and the like disclosed herein, including those illustrated in the drawings are merely examples, and thus, the present disclosure is not limited to the illustrated details. Any implementation described herein as an “example” is not necessarily to be construed as preferred or advantageous over other implementations. It is, however, noted that the relative dimensions of the components illustrated in the drawings are part of the present disclosure.

When the term “comprise,” “have,” “include,” “contain,” “constitute,” “made of,” “formed of,” or the like is used with respect to one or more elements, one or more other elements may be added unless a term such as “only” or the like is used. The terms used in the present disclosure are merely used in order to describe example embodiments, and are not intended to limit the scope of the present disclosure. The terms of a singular form may include plural forms unless the context clearly indicates otherwise.

In construing an element, the element is construed as including an error region although there is no explicit description thereof.

In describing a positional relationship, for example, when the positional order is described as “on,” “above,” “below,” “beneath,” and “next,” the case of no contact therebetween may be included, unless “just” or “direct” is used.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element is “connected,” “coupled,” “attached,” “adhered,” or the like to another element, the element may not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element is “contacts,” “overlaps,” or the like with another element, the element may not only directly contact, overlap, or the like with another element, but also indirectly contact, overlap, or the like with another element with one or more intervening elements disposed or interposed between the elements, unless otherwise specified.

The term “at least one” should be understood as including any and all combinations of one or more of the associated listed items. For example, “at least one among a first element, a second element and a third element” may include all combinations of two or more elements selected from the first, second and third elements as well as each element of the first, second and third elements.

Features of various embodiments of the present disclosure may be partially or entirety coupled to or combined with each other, may be technically associated with each other, and may be variously inter-operated, linked or driven together. The embodiments of the present disclosure may be implemented or carried out independently of each other, or may be implemented or carried out together in a co-dependent or related relationship. In one or more aspects, the components of each apparatus according to various embodiments of the present disclosure are operatively coupled and configured.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

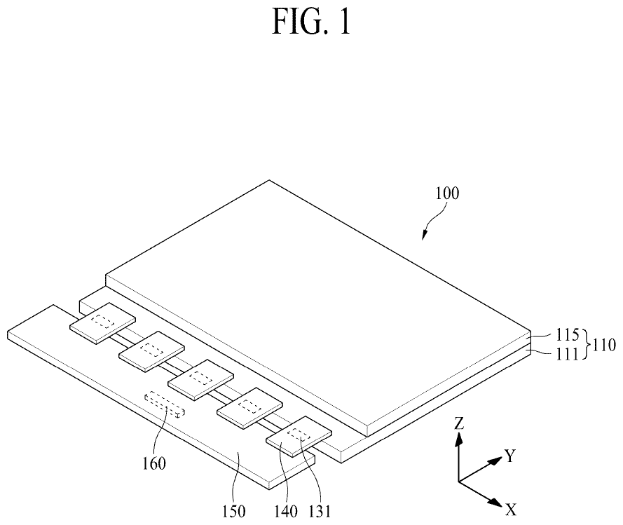

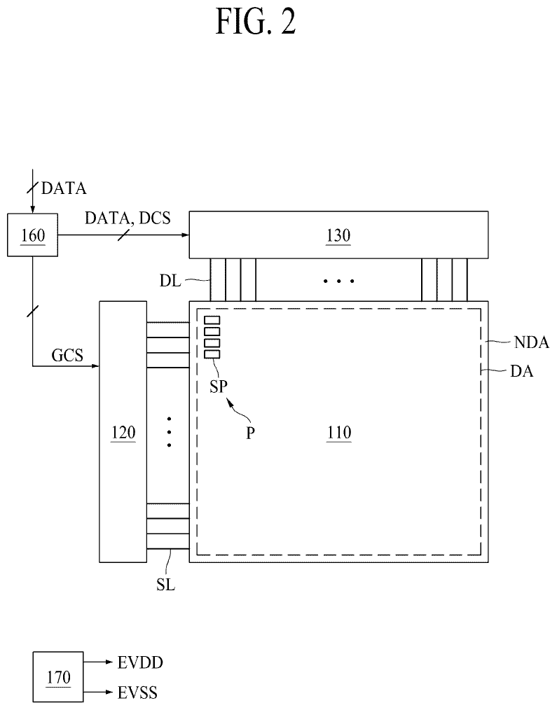

FIG. 1 illustrates a light emitting display apparatus according to an embodiment of the present disclosure. FIG. 2 is a block diagram illustrating a light emitting display apparatus according to an embodiment of the present disclosure.

A light emitting display apparatus 100 according to an embodiment of the present disclosure is implemented as an organic light emitting display apparatus, but may also be implemented as a liquid crystal display apparatus, a micro light emitting diode LED display apparatus, a quantum dot lighting emitting diode display apparatus, or an electrophoretic display apparatus.

Referring to FIGS. 1 and 2, the light emitting display apparatus 100 according to an embodiment of the present disclosure may include a display panel 110, a scan driver 120 embedded in the display panel 110, a data driver 130 connected to the display panel 110, a timing controller 160 controlling the scan driver 120 and the data driver 130, and a power circuit 170.

The display panel 110 may include a substrate 111 and an opposite substrate 115. The opposing substrate 115 may be an encapsulation substrate. The substrate 111 may include a plastic film or a glass substrate, but embodiments of the present disclosure are not limited thereto. For example, the substrate 111 may be formed of a semiconductor material such as a silicon wafer. The opposite substrate 115 may be a plastic film, a glass substrate, or an encapsulation film (or protection film).

The display panel 110 includes a display area DA and a non-display area NDA extending from the display area DA. As an example, the non-display area NDA may partially or fully surround the display area DA. The display panel 110 includes pixels P provided in the display area DA to display an image. Each of the pixels P may include a plurality of subpixels SP. The structure of the subpixel SP may be variously changed according to the type of the light emitting display apparatus 100. For example, the subpixels SP may be formed in a top emission type, a bottom emission type, or a dual emission type according to the structure. The subpixels SP indicate a unit capable of forming a color filter of a specific type or capable of emitting a color of itself without forming a color filter. For example, the subpixels SP may include a red subpixel, a green subpixel, and a blue subpixel. Alternatively, the subpixels SP may include a red subpixel, a blue subpixel, a white subpixel, and a green subpixel. Embodiments are not limited thereto. As an example, sub pixels of other colors such as cyan, magenta, or yellow, etc. may be alternatively or additionally included. The subpixels SP may have one or more other light-emitting areas according to light-emitting characteristics. For example, the plurality of subpixels SP may be arranged in a quad type or a stripe type, but embodiments of the present disclosure are not limited thereto. The color type, arrangement type, arrangement order, and the like of the subpixels SP may be configured in various forms according to the light-emitting characteristics, lifespan of the apparatus, spec of the apparatus, and the like.

The display panel 110 may include data lines DL and scan lines SL connected to the subpixels SP. The data lines DL may be arranged to cross the scan lines SL. Each of the subpixels SP of the display panel 110 may be connected to any one of the data lines DL and any one of the scan lines SL. The data lines DL may supply a data voltage supplied from the data driver 130 to each of the subpixels SP. The scan lines SL may supply a scan signal supplied from the scan driver 120 to each of the subpixels SP.

Each of the subpixels SP is turned-on by the scan signal. When the data voltage of the data line DL is supplied to a gate electrode of a driving transistor, a light emitting element may emit light according to a drain-to-source current of the driving transistor. The scan driver 120 may receive a scan control signal GCS from the timing controller 160. The scan driver 120 may supply the scan signals or emission control signal to the scan lines SL by using the scan control signal GCS.

The scan driver 120 may be configured in a gate driver in panel GIP manner in the non-display area NDA outside one side or both sides of the display area DA. Alternatively, the scan driver 120 may be manufactured as a driving chip, mounted on a flexible film, and attached to the non-display area NDA outside one side or both sides of the display area DA in a tape automated bonding TAB manner, or may be attached to the non-display area NDA outside one side or both sides of the display area DA in a chip on glass (COG) manner, a chip on panel (COP) manner, or a chip on film (COF) manner, etc., without being limited thereto.

The data driver 130 may receive digital video data DATA and a data control signal DCS from the timing controller 160. The data driver 130 converts the digital video data DATA into analog positive/negative data voltages by using the data control signal DCS and supplies the analog positive/negative data voltages to the data lines DL.

The data driver 130 may include a plurality of data drive ICs 131 as shown in FIG. 1. Each of the plurality of data drive ICs 131 may be mounted on the flexible film 140 by chip on film COF, chip on plastic COP, Flexible Printed Circuit FPC, or Flexible Flat Cable FFC. The flexible film 140 is attached on pads provided in the non-display area NDA of the display panel 110 by using an anisotropic conducting film, whereby the plurality of data drive ICs 131 may be connected to the pads.

The circuit board 150 may be attached to the flexible films 140. A plurality of circuits implemented as driving chips may be mounted on the circuit board 150. For example, the timing controller 160 may be mounted on the circuit board 150. The circuit board 150 may be a printed circuit board or a flexible printed circuit board.

The timing controller 160 receives digital video data DATA and timing signals from a host system. The timing signals may include a vertical synchronization signal, a horizontal synchronization signal, a data enable signal, a dot clock, and the like. The vertical synchronization signal is a signal defining one frame period. The horizontal synchronization signal is a signal defining one horizontal period required for supplying the data voltages to the pixels of one horizontal line of the display panel 110. The data enable signal defines a period in which valid data is input. The dot clock is a signal repeated at a predetermined short period.

The timing controller 160 may generate the data control signal DCS for controlling an operation timing of the data driver 130 and the scan control signal GCS for controlling an operation timing of the scan driver 120 based on the timing signals. The timing controller 160 may output the scan control signal GCS to the scan driver 120 and output the digital video data DATA and data control signal DCS to the data driver 130.

The power circuit 170 may generate and supply a plurality of driving voltages required for an operation of all circuit configurations of the display apparatus 100 by using an input voltage. The power circuit 170 may generate a first power supply voltage EVDD (or pixel power voltage), a second power supply voltage EVSS (or common power voltage) and an initialization voltage Vref (or reference voltage) and supply the generated voltages to the display panel 110. The power circuit 170 may generate and supply various driving voltages required for operations of the gate driver 120, the data driver 130, and the timing controller 160.

The power circuit 170 according to an embodiment of the present disclosure may divide the second power supply voltage EVSS into a first common power voltage and a second common power voltage and may generate the first common power voltage and the second common power voltage. For example, the first common power voltage and the second common power voltage may have the same voltage level or different voltage levels. For example, the first common power voltage and the second common power voltage may have a constant voltage difference therebetween, and the first common power voltage may have a lower voltage level than the second common power voltage, or conversely, a higher voltage level, but embodiments of the present disclosure are not limited thereto.

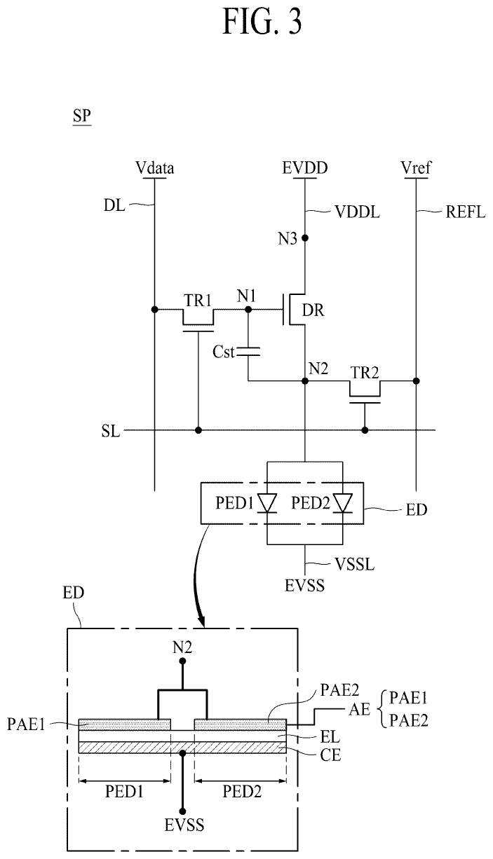

FIG. 3 is a circuit diagram illustrating a subpixel of a light emitting display apparatus according to an embodiment of the present disclosure.

Referring to FIG. 3, each of pixels includes a plurality of subpixels SP constituting a unit pixel. In each of the plurality of subpixels SP, there are a pixel circuit having 3T (Transistor) 1C (Capacitor) including a driving transistor DR, a first switching transistor TR1, a second switching transistor TR2 and a storage capacitor Cst, and a light emitting element ED, but not limited thereto. Each subpixel SP may further include a compensation circuit. In this case, the subpixel SP may have various structures such as 2T1C, 4T2C, 5T2C, 6T1C, 6T2C, 7T1C, and 7T2C.

At least one thin film transistor DR, TR1 and TR2 of each subpixel SP may include a gate electrode, a source electrode, and a drain electrode. Since the source electrode and the drain electrode may be changed according to a voltage and a current direction applied to the gate electrode without being fixed, any one of the source electrode and the drain electrode may be represented as a first electrode, and the other may be represented as a second electrode. The at least one transistor DR, TR1, and TR2 may use at least one of polysilicon semiconductor, amorphous silicon semiconductor, and oxide semiconductor. The transistors DR, TR1, and TR2 may be P-type or N-type, or P-type and N-type may be interchangeably used.

The driving transistor DR corresponds to a transistor for driving the light emitting element ED, and the driving transistor DR includes a first node N1 to which a data voltage Vdata is applied, a second node N2 connected to a first electrode AE (pixel electrode or anode electrode) of the light emitting element ED, and a third node N3 connected to a pixel power line VDDL (or first power line) and supplied with a first power supply voltage EVDD (or pixel power voltage). For example, the first node N1 may be a gate node of the driving transistor DR, the second node N2 may be a source or drain node of the driving transistor DR, and the third node N3 may be a source or drain node of the driving transistor DR. For example, the second node N2 may be a source node, and the third node N3 may be a drain node, but embodiments of the present disclosure are not limited thereto.

The first switching transistor TR1 may serve to supply the data voltage Vdata supplied from the data line DL to the driving transistor DT. The first switching transistor TR1 may switch an electrical connection between the data line DL and the first node N1. For example, the first switching transistor TR1 may be turned-on in response to the scan signal Scan applied through a scan line SL (or gate line). When the first switching transistor TR1 is turned-on, the data voltage Vdata applied through the data line DL may be transferred to the first node N1.

The second switching transistor TR2 may serve to supply a reference voltage Vref supplied from a reference line REFL to a driving transistor DR or may output a voltage of a second node N2 of the driving transistor DR. The second switching transistor TR2 may switch an electrical connection between the reference line REFL and the second node N2. For example, the second switching transistor TR2 may be turned-on in response to a scan signal applied through a scan line SL (or gate line). When the second switching transistor TR2 is turned-on, the reference voltage Vref applied through the reference line REFL may be transferred to the second node N2, or when the second switching transistor TR2 is turned-on, the voltage of the second node N2 of the driving transistor DR may be output to the reference line REFL. Although it is illustrated and described that the first switching transistor TR1 and the second switching transistor TR2 may be turned-on in response to the scan signal applied through the same scan line SL (or gate line), embodiments are not limited thereto. As an example, the first switching transistor TR1 and the second switching transistor TR2 may be turned-on in response to scan signals applied through different scan lines. In this case, as an example, the first switching transistor TR1 and the second switching transistor TR2 may be driven independently, without being limited thereto.

The storage capacitor Cst maintains the data voltage Vdata supplied to the driving transistor DR for a period (e.g., one frame). The storage capacitor Cst may be connected between the first node N1 and the second node N2. For example, the storage capacitor Cst may store the voltage corresponding to the data voltage Vdata transferred through the first switching transistor TR1 and may turn on the driving transistor DR with the stored voltage.

The light emitting element ED may include the first electrode AE (pixel electrode or anode electrode) connected to the driving transistor, the second electrode CE (common electrode or cathode electrode) receiving a second power voltage EVSS (or common power voltage) from a common power line VSSL (or second power line), and an emission layer (or organic light emitting layer) between the first electrode AE and the second electrode CE. The first electrode AE is an independent electrode for each light emitting element, but the second electrode CE may be a common electrode shared by the entire light emitting elements. When a driving current is supplied from the driving transistor DR, electrons from the second electrode CE are injected into the emission layer EL, and holes from the first electrode AE are injected into the emission layer EL, whereby fluorescent or phosphorescent materials emit through recombination of electrons and holes in the emission layer EL, thereby generating light of brightness proportional to a current value of the driving current.

The first electrode AE of the light emitting element ED may be connected to the second node N2 of the driving transistor DR, and the second electrode CE of the light emitting element ED may be connected to the common power line VSSL. The light emitting element ED may emit light in response to the driving current generated by the driving transistor DR.

The light emitting element ED according to an embodiment of the present disclosure may comprise a first partial light emitting element PED1 and a second partial light emitting element PED2. The first partial light emitting element PED1 and the second partial light emitting element PED2 may be connected in common to the second node N2 of the driving transistor DR. A first electrode AE of the light emitting element ED may be divided into a first divided electrode PAE1 (or first divided pixel electrode) and a second divided electrode PAE2 (or second divided pixel electrode). A second electrode CE of the light emitting element ED may be provided in common for the first partial light emitting element PED1 and the second partial light emitting element PED2. For example, second electrode CE of the light emitting element ED may be connected in common to the first divided electrode PAE1 and the second divided electrode PAE2. The second electrode CE receives a second power voltage EVSS from a common power line VSSL and applies the second power voltage EVSS to the first partial light emitting element PED1 and the second partial light emitting element PED2. For example, the second electrode CE receives a second power voltage EVSS from a common power line VSSL and applies the second power voltage EVSS to the first divided electrode PAE1 and the second divided electrode PAE2.

The first partial light emitting element PED1 may include the first divided electrode PAE1, the emission layer EL, and the second electrode CE. In addition, the second partial light emitting element PED2 may include the second divided electrode PAE2, the emission layer EL, and the second electrode CE. According to an embodiment of the present disclosure, the light emitting element ED of each subpixel SP may include the first partial light emitting element PED1 and the second partial light emitting element PED2 by the first electrode AE divided into the first divided electrode PAE1 and the second divided electrode PAE2.

The light emitting element ED of each subpixel SP according to an embodiment of the present disclosure is configured to be divided into the first partial light emitting element PED1 and the second partial light emitting element PED2. When a short occurs due to foreign substances in any one of the first partial light emitting element PED1 and the second partial light emitting element PED2 during a panel manufacturing process or after completion of panel production, a repair process may be carried out by darkening only the partial light emitting element with the short, and normally operating the remaining partial light emitting element. Embodiments are not limited thereto. As an example, each subpixel SP according to an exemplary embodiment of the present disclosure may also comprise one single light emitting element or three or more the partial light emitting elements.

The repair process according to an embodiment of the present disclosure may include an aging repair process and a semi-dark repair process for removing an anode-cathode short AC short during the repair process after the panel manufacturing process or after shipping of panel product. For example, the aging repair process may remove the anode-cathode short with Joule Heating that generates heat from an anode-cathode short portion by applying a reverse bias voltage between the second electrode CE and the second node N2 of the driving transistor DT.

The semi-dark repair process checks the anode-cathode short portion, which is not removed by the aging repair process, as naked eyes (or a microscope) of a worker and carries out a cutting process by applying laser or physical force to the divided electrode of the partial light emitting element with the anode-cathode short of the first partial light emitting element PED1 and the second partial light emitting element PED2 of the light emitting element ED, whereby the half (½) of the light emitting element ED may be darkened, and the remaining half (½) of the light emitting element ED may be normally operated. However, in the light emitting display apparatus according to an embodiment of the present disclosure, since a worker observes foreign substances with naked eye in the semi-dark repair process and proceeds with the repair process, a tact time is long. Also, when foreign matters are not seen, a repair success rate is lowered. In addition, another processing anode-cathode short may occur even after the semi-dark repair process is performed so that it is difficult to manage the yield of the light emitting display apparatus. Accordingly, the inventors of the present disclosure have invented a light emitting display apparatus having a new structure, which is capable of automatically detecting a semi-dark repair target for a semi-dark repair process and accurately detecting the semi-dark repair target, through various studies.

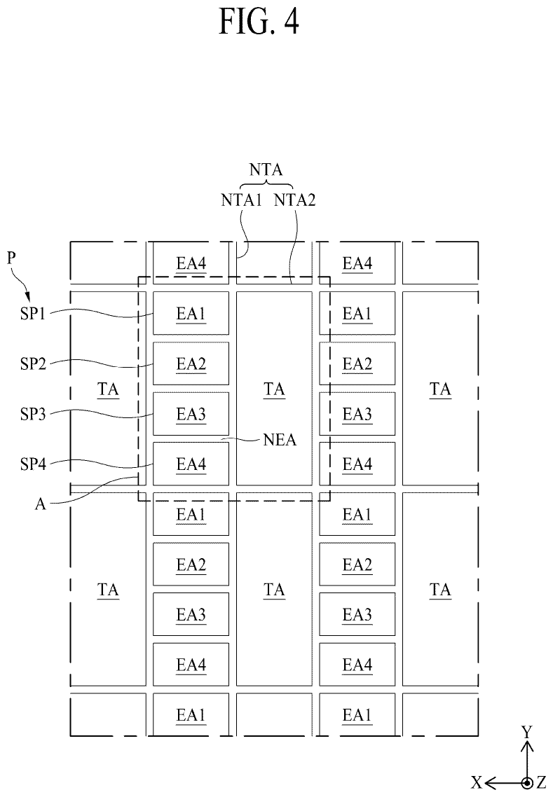

Hereinafter, a light emitting display apparatus according to an embodiment of the present disclosure capable of automatically detecting a semi-dark repair target in a semi-dark repair process and accurately detecting the semi-dark repair target will be described in more detail with reference to FIGS. 4 to 25.

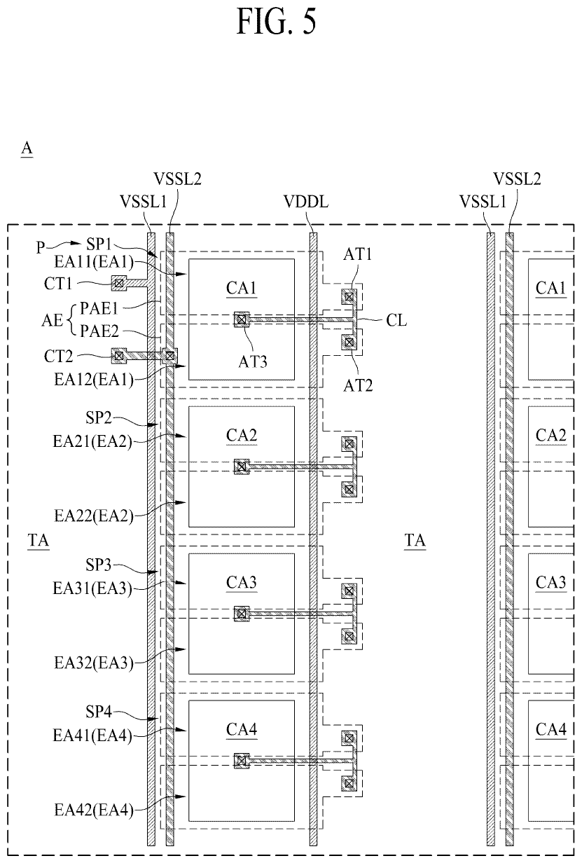

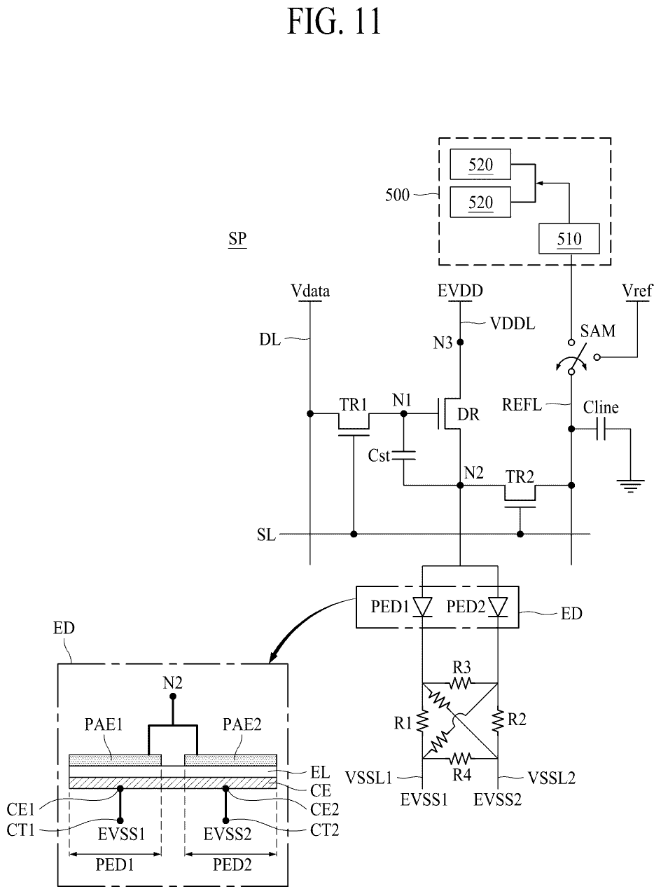

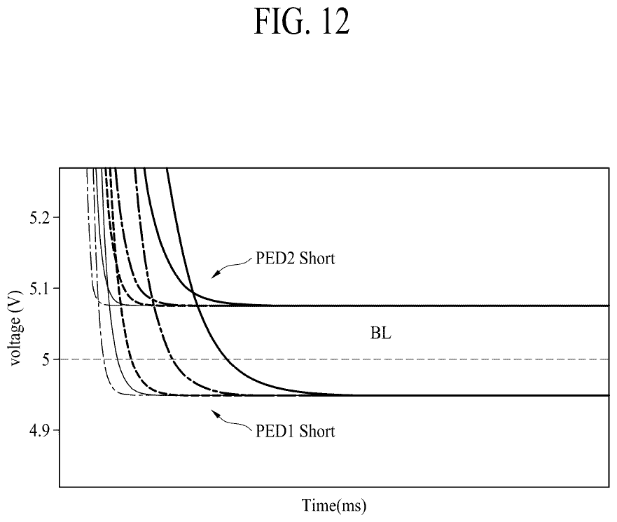

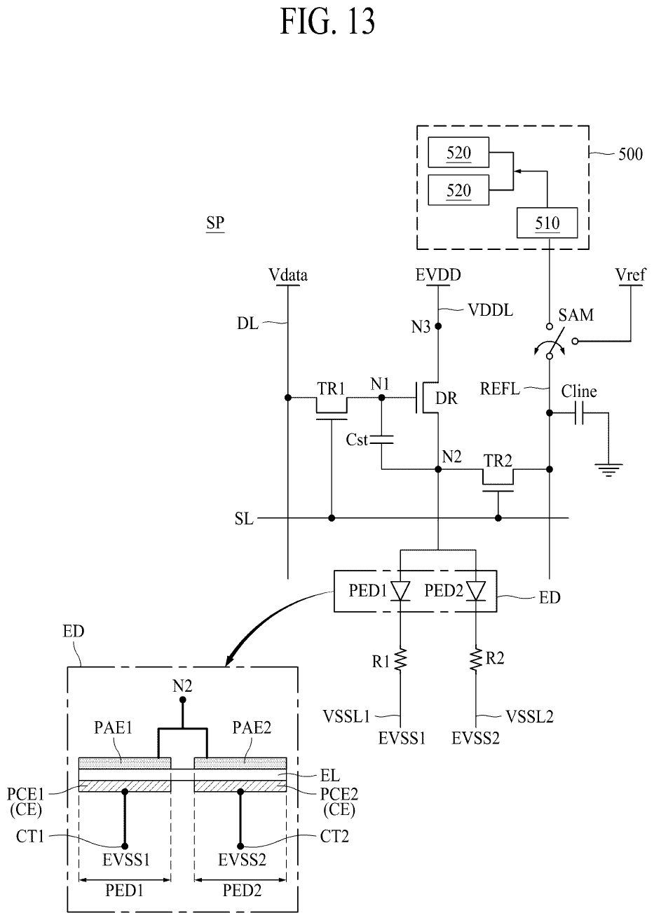

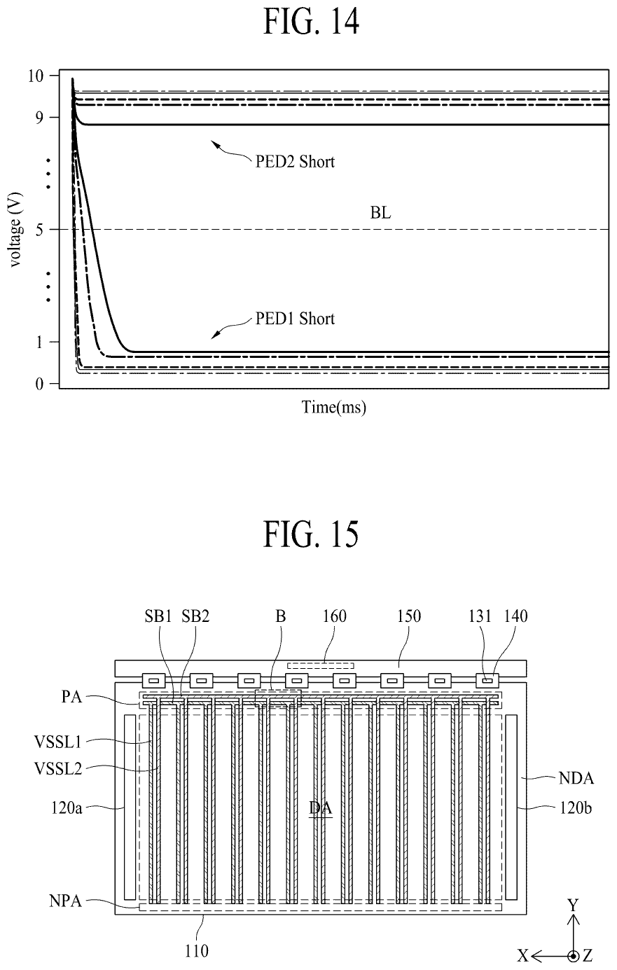

FIG. 4 illustrates a pixel of a light emitting display apparatus according to an embodiment of the present disclosure. FIGS. 5 to 10 illustrate a region A shown in FIG. 4 according to various embodiments of the present disclosure. FIG. 11 illustrates a subpixel and a repair detecting part in a light emitting display apparatus according to an embodiment of the present disclosure. FIG. 12 illustrates a voltage measurement value of a repair detecting part shown in FIG. 11 according to an embodiment of the present disclosure. FIG. 13 illustrates a subpixel and a repair detecting part of a light emitting display apparatus according to another embodiment of the present disclosure. FIG. 14 illustrates a voltage measurement value of a repair detecting part shown in FIG. 13 according to another embodiment of the present disclosure.

Referring to FIGS. 4 to 14, each of pixels P of the light emitting display apparatus according to an embodiment of the present disclosure may include a transmission area TA and a non-transmission area NTA in which a plurality of subpixels SP1, SP2, SP3, and SP4 representing different colors are disposed. For example, in FIGS. 4 to 9, each pixel P is illustrated as a transparent display panel including a transmission area TA, but embodiments of the present disclosure are not limited thereto. Herein, each pixel P may be a light emitting display panel which does not include a transmission area TA.

Referring to FIG. 4, in each pixel P, the plurality of subpixels SP1, SP2, SP3, and SP4 may be disposed adjacent to each other in a first direction (or Y-axis direction). Also, the transmission area TA may be disposed adjacent to the plurality of subpixels SP1, SP2, SP3, and SP4 in a second direction (or X-axis direction). Embodiments are not limited thereto. As an example, the plurality of subpixels SP1, SP2, SP3, and SP4 may be disposed adjacent to each other in a second direction (or X-axis direction) or a direction other than the first direction and the second direction. As an example, the plurality of subpixels SP1, SP2, SP3, and SP4 may be disposed in an array with rows and columns. For example, the transmission area TA may be an area through which most of light incident from the outside passes, and the non-transmission area NTA may be an area which does not transmit most of light incident from the outside. For example, the transmission area TA may be an area in which the light transmittance is greater than a %, and the non-transmission area NTA may be a region in which the light transmittance is less than b %. Herein, ‘a’ may be a value greater than ‘b.’ The light emitting display apparatus according to the embodiment of the present disclosure may view an object or a background located on a rear surface (or back surface) of a display panel 110 through transmission areas TA.

The non-transmission area NTA may include a first non-transmission area NTA1, a second non-transmission area NTA2, and the plurality of subpixels SP1, SP2, SP3, and SP4.

The first non-transmission area NTA1 extends in the display panel 110 in the first direction (or Y-axis direction), and at least a portion of the first non-transmission area NTA1 may be disposed to overlap with emission areas EA1, EA2, EA3, and EA4 of each of the subpixels SP1, SP2, SP3, and SP4.

There may be the plurality of first non-transmission areas NTA1. The plurality of first non-transmission areas NTA1 may extend in the first direction (or Y-axis direction) and may be spaced apart from each other in the second direction (or X-axis direction). The two adjacent first non-transmission areas NTA1 may be arranged to be spaced apart from each other with the transmission area TA interposed therebetween. For example, the transmission area TA may be arranged between the two adjacent first non-transmission areas NTA1. At least one first signal line extending in the first direction (or Y-axis direction) may be disposed in the first non-transmission area NTA1. For example, the at least one first signal line may be disposed to overlap the first non-transmission area NTA1. For example, the at least one first signal line may include at least one of a pixel power line VDDL (or first power line), a common power line VSSL (or second power line), a reference line REFL, and data lines DL, but embodiments of the present disclosure are not limited thereto.

The second non-transmission area NTA2 may extend in the second direction (or X-axis direction) in the display panel 110 For example, at least a portion of the second non-transmission area NTA2 may be disposed to overlap the emission areas EA1, EA2, EA3, and EA4 of each of the subpixels SP1, SP2, SP3, and SP4, without being limited thereto. For example, at least a portion of or the entirety of the second non-transmission area NTA2 may be disposed to not overlap the emission areas EA1, EA2, EA3, and EA4 of each of the subpixels SP1, SP2, SP3, and SP4. As an example, at least a portion of the second non-transmission area NTA2 may be disposed between adjacent emission areas. For example, the second non-transmission area NTA may extend in the second direction (or X-axis direction) between the two adjacent first non-transmission areas NTA1. There may be the plurality of second non-transmission areas NTA2. The plurality of second non-transmission areas NTA2 may extend in the second direction (or X-axis direction) and may be spaced apart from each other in the first direction (or Y-axis direction). The two adjacent second non-transmission areas NTA2 may be arranged to be spaced apart from each other with the transmission area TA interposed therebetween. For example, the transmission area TA may be arranged between the two adjacent second non-transmission areas NTA2. At least one second signal line extending in the second direction (or X-axis direction) may be disposed in the second non-transmission area NTA2. For example, the at least one second signal line may be disposed to overlap the second non-transmission area NTA2. For example, the at least one second signal line may include a scan line SL (or gate line), but embodiments of the present disclosure are not limited thereto.

Each pixel P is disposed in each intersection where a first non-transmission area NTA1 and a second non-transmission area NTA2 intersect, and each pixel P emits light to display an image. Each pixel P may include emission areas EA1, EA2, EA3, and EA4 which emit light in response to the plurality of subpixels SP1, SP2, SP3, and SP4 including a light emitting element. The emission area EA1, EA2, EA3, and EA4 may correspond to an area in which light is emitted from the pixel P. The emission areas EA1, EA2, EA3, and EA4 may be disposed to overlap pixel circuits of the plurality of subpixels SP1, SP2, SP3, and SP4. For example, the emission areas EA1, EA2, EA3, and EA4 may at least partially overlap circuit areas CA1, CA2, CA3, and CA4 in which the pixel circuit is disposed. For example, the circuit areas CA1, CA2, CA3, and CA4 may include the first circuit area CA1 in which the pixel circuit connected to the first subpixel SP1 is disposed, the second circuit area CA2 in which the pixel circuit connected to the second subpixel SP2 is disposed, the third circuit area CA3 in which the pixel circuit connected to the third subpixel SP3 is disposed, and the fourth circuit area CA4 in which the pixel circuit connected to the fourth subpixel SP4 is disposed. Embodiments are not limited thereto. As an example, only one or some of the emission areas EA1, EA2, EA3, and EA4 may be disposed to overlap pixel circuits of the plurality of subpixels SP1, SP2, SP3, and SP4. As an example, pixel circuits of two or more of the plurality of subpixels SP1, SP2, SP3, and SP4 may overlap one of the emission areas EA1, EA2, EA3, and EA4. As an example, the pixel circuit of one of the plurality of subpixels SP1, SP2, SP3, and SP4 may overlap two or more of the emission areas EA1, EA2, EA3, and EA4.

The first to fourth emission areas EA1, EA2, EA3, and EA4 corresponding to the plurality of subpixels SP1, SP2, SP3, and SP4 may emit light of different colors. For example, the first emission area EA1 may emit green light, the second emission area EA2 may emit blue light, the third emission area EA3 may emit white light, and the fourth emission area EA4 may emit red light, but embodiments of the present disclosure are not limited thereto. For example, two or more of the first to fourth emission areas EA1, EA2, EA3, and EA4 corresponding to the plurality of subpixels SP1, SP2, SP3, and SP4 may emit light of the same colors, without being limited thereto. For example, the plurality of subpixels SP1, SP2, SP3, and SP4 may be configured in a stripe type arranged in the first direction (or Y-axis direction) or a quad type arranged in the first direction and the second direction (or X-axis direction), but not limited thereto. The arrangement order or type of the plurality of subpixels may be variously changed.

The light emitting display apparatus according to an embodiment of the present disclosure may include a common power line VSSL (or second power line) for supplying a common power voltage EVSS (or second power voltage) to each of the plurality of subpixels SP1, SP2, SP3, and SP4. The common power line VSSL may be divided into a first common power line VSSL1 and a second common power line VSSL2. For example, the common power voltage EVSS may be a low potential power voltage applied to the second electrode CE (common electrode or cathode electrode) of the light emitting element ED included in the plurality of subpixels SP1, SP2, SP3, and SP4. The first common power line VSSL1 and the second common power line VSSL2 may be applied with the same common power voltage EVSS, or the first common power voltage VSS1 and the second common power voltage VSS2 having different voltage levels may be applied to the first common power line VSSL1 and the second common power line VSSL2. In addition, the first electrode AE (pixel electrode or anode electrode) of the light emitting element ED included in each of the plurality of subpixels SP1, SP2, SP3, and SP4 may include the first divided electrode PAE1 (or first divided pixel electrode) and the second divided electrode PAE2 (or second divided pixel electrode) divided from each other. Accordingly, the light emitting display apparatus according to an embodiment of the present disclosure may include the plurality of emission areas EA1, EA2, EA3, and EA4 divided into two parts and included in each of the plurality of subpixels SP1, SP2, SP3, and SP4. FIGS. 5 to 10 illustrate various embodiments of the arrangement structure of the first and second common power lines VSSL1 and VSSL2 and the first and second divided electrodes PAE1 and PAE2. In the following description with reference to FIGS. 5 to 10, same reference numerals refer to same configurations except for different configurations, and redundant descriptions will be omitted or briefly described.

Referring to FIG. 5, the light emitting display apparatus according to an embodiment of the present disclosure may include the plurality of subpixels SP1, SP2, SP3, and SP4, a first power line (or pixel power line) VDDL, a first common power line VSSL1, and a second common power line VSSL2.

The plurality of subpixels SP1, SP2, SP3, and SP4 may include the plurality of emission areas divided into the plurality. For example, in each of the plurality of subpixels SP1, SP2, SP3, and SP4, the first electrode AE (pixel electrode or anode electrode) of the light emitting element ED may include the first divided electrode PAE1 (or first divided pixel electrode) and the second divided electrode PAE2 (or second divided pixel electrode) spaced apart from each other in the first direction (or Y-axis direction) or the second direction (or X-axis direction). For example, as shown in FIG. 5, the first divided electrode PAE1 and the second divided electrode PAE2 may be disposed adjacent to each other in the first direction.

As shown in FIG. 11 or 13, the light emitting element ED of each of the plurality of subpixels SP1, SP2, SP3, and SP4 may include the first electrode AE (pixel electrode or anode electrode), an emission layer EL (or an organic emission layer), and the second electrode CE (common electrode or cathode electrode). The light emitting element ED may include a first partial light emitting element PED1 and a second partial light emitting element PED2. The first partial light emitting element PED1 and the second partial light emitting element PED2 may respectively correspond to the divided first and second divided electrodes PAE1 and PAE2 of the first electrode AE. For example, the first partial light emitting element PED1 may include the first divided electrode PAE1, the emission layer EL overlapping the first divided electrode PAE1, and the second electrode CE. In addition, the second partial light emitting element PED2 may include the second divided electrode PAE2, the emission layer EL overlapping the second divided electrode PAE2, and the second electrode CE. For example, as shown in FIG. 11, the emission layer EL and the second electrode CE may be commonly included in the first partial light emitting element PED1 and the second partial light emitting element PED2. Alternatively, as shown in FIG. 13, the emission layer EL may be commonly included in the first partial light emitting element PED1 and the second partial light emitting element PED2. The second electrode CE may include a first common electrode PCE1 and a second common electrode PCE2, which are separated from each other to correspond to the first and second divided electrodes PAE1 and PAE2, respectively. The first common electrode PCE1 may be included in the first partial light emitting element PED1. The second common electrode PCE2 may be included in the second partial light emitting element PED2.

The first emission area EA1 included in the first subpixel SP1 may include a first divided emission area EA1l and a second divided emission area EA12 respectively corresponding to the first and second divided electrodes PAE1 and PAE2 divided into the two. The second emission area EA2 included in the second subpixel SP2 may include a first divided emission area EA21 and a second divided emission area EA22 respectively corresponding to the first and second divided electrodes PAE1 and PAE2 divided into the two. The third emission area EA3 included in the third subpixel SP3 may include a first divided emission area EA31 and a second divided emission area EA32 respectively corresponding to the first and second divided electrodes PAE1 and PAE2 divided into the two. The fourth emission area EA4 included in the fourth subpixel SP4 may include a first divided emission area EA41 and a second divided emission area EA42 respectively corresponding to the first and second divided electrode PAE1 and PAE2 divided into the two.

As shown in FIG. 11 or 13, the circuit area CA1, CA2, CA3, and CA4 of the plurality of subpixels SP1, SP2, SP3, and SP4 may include a pixel circuit including at least one thin film transistor DR, TR1, and TR2 and a storage capacitor Cst. For example, the at least one thin film transistor DR, TR1, and TR2 may include a driving transistor DR, a first switching transistor TR1, and a second switching transistor TR2. The pixel circuit of each of the plurality of subpixels SP1, SP2, SP3, and SP4 may be connected in common to the first divided electrode PAE1 and the second divided electrode PAE2.

Referring to FIG. 5, the first divided electrode PAE1 and the second divided electrode PAE2 may be electrically connected to each other through a connection line CL. The connection line CL may serve to repair darkening in any one of the first and second divided electrodes PAE1 and PAE2. For example, the connection line CL may electrically connect the first divided electrode PAE1 and the second divided electrode PAE2 to the circuit area CA1, CA2, CA3, and CA4 of each of the subpixels SP1, SP2, SP3, and SP4. For example, the connection line CL may be connected between at least one of the first divided electrode PAE1 and the second divided electrode PAE2 and corresponding one of the circuit area CA1, CA2, CA3, and CA4 of the subpixels SP1, SP2, SP3, and SP4. For example, the connection line CL may be configured in “T” shape, but embodiments of the present disclosure are not limited thereto. One end of the connection line CL may be branched to both sides to be electrically connected to first and second contact portions AT1 and AT2 of the first and second divided electrodes PAE1 and PAE2. In addition, the other end of the connection line CL may be electrically connected to a third contact portion AT3 of corresponding one of the circuit area CA1, CA2, CA3, and CA4 of the subpixels SP1, SP2, SP3, and SP4.

When foreign substances are generated in any one of the first divided electrode PAE1 and the second divided electrode PAE2, the connection line CL may serve to separate or disconnect the electrical connection between the divided electrode in which the foreign substances are generated and the circuit areas CA1, CA2, CA3, and CA4, thereby darkening only the divided electrode in which foreign substances are generated and repairing the remaining divided electrode to be normally operated. For example, the divided electrode, in which the foreign substances are generated, among the first divided electrode PAE1 and the second divided electrode PAE2 may be electrically separated or disconnected from the connection line CL, and the divided electrode without the foreign substances among the first divided electrode PAE1 and the second divided electrode PAE2 may be electrically connected to the circuit areas CA1, CA2, CA3, and CA4 through the connection line CL.

Referring to FIG. 5, the first power line VDDL (or pixel power line) may supply a first power voltage EVDD (or pixel power voltage) to the driving transistor DR of each of the subpixels SP1, SP2, SP3, and SP4. The first power line VDDL may extend in the first direction (or Y-axis direction) of the display panel 110 and may be disposed on the right or left side in the second direction (or X-axis direction) of the plurality of subpixels SP1, SP2, SP3, and SP4. For example, as shown in FIG. 5, the first power line VDDL may be disposed on the right side in the second direction (or X-axis direction) of the plurality of subpixels SP1, SP2, SP3, and SP4, but embodiments of the present disclosure are not limited thereto.

Referring to FIG. 5, the light emitting display apparatus according to an embodiment of the present disclosure may be configured by dividing the second power line VSSL (or common power line) for supplying the second power voltage EVSS (or common power voltage) into the first common power line VSSL1 and the second common power line VSSL2. For example, as shown in FIG. 11, the first common power line VSSL1 and the second common power line VSSL2 may be connected in common to the common electrode CE of the light emitting element ED. Alternatively, as shown in FIG. 13, the common electrode CE of the light emitting element ED may be divided into the first common electrode PCE1 and the second common electrode PCE2, the first common power line VSSL1 may be connected to the first common electrode PCE1, and the second common power line VSSL2 may be connected to the second common electrode PCE2.

The first common power line VSSL1 may supply the first common power voltage EVSS1 to the common electrode CE of the light emitting element ED, and the second common power line VSSL2 may supply the second common power voltage EVSS2 to the common electrode CE of the light emitting element ED. Alternatively, the first common power line VSSL1 may supply the first common power voltage EVSS1 to the first common electrode PCE1 of the common electrode CE, and the second common power line VSSL2 may supply the second common power voltage EVSS2 to the second common electrode PCE2 of the common electrode CE.

According to an embodiment of the present disclosure, the first divided electrode PAE1 and the second divided electrode PAE2 of the first electrode AE may have different electrical distances with respect to the first common power line VSSL1 and the second common power line VSSL2. For example, the electrical distance may be a distance in which a resistance, voltage, or current is changed. For example, the first electrical distance of the first divided electrode PAE1 may correspond to the resistance between the common electrode CE overlapping the first divided electrode PAE1 and the first common power line VSSL1, and the second electrical distance of the second divided electrode PAE2 may correspond to the resistance between the common electrode CE overlapping the second divided electrode PAE2 and the second common power line VSSL2. For example, the first electrical distance of the first divided electrode PAE1 may correspond to the resistance between a portion of the common electrode CE overlapping the first divided electrode PAE1 and a cathode contact portion CT1 of the first common power line VSSL1, and the second electrical distance of the second divided electrode PAE2 may correspond to the resistance between a portion of the common electrode CE overlapping the second divided electrode PAE2 and a cathode contact portion CT2 of the second common power line VSSL2. For example, the first partial light emitting element PED1 and the second partial light emitting element PED2 may be applied with the first common power voltage EVSS1 and the second common power voltage EVSS2 from the first common power line VSSL1 and the second common power line VSSL2 through the common electrode CE of the light emitting element ED. For example, the first common power voltage EVSS1 and the second common power voltage EVSS2 may be simultaneously applied to the first partial light emitting element PED1 and the second partial light emitting element PED2. For example, the first common power voltage EVSS1 and the second common power voltage EVSS2 may have the same voltage level or different voltage levels. The light emitting display apparatus according to an embodiment of the present disclosure may control the first common power voltage EVSS1 and the second common power voltage EVSS2 to have the same voltage level in a normal driving state. Also, in order to detect a semi-dark repair target for a semi-dark repair process, the light emitting display apparatus according to an embodiment of the present disclosure may control the first common power voltage EVSS1 and the second common power voltage EVSS2 to have different voltage levels. For example, in order to detect a semi-dark repair target, a power circuit 170 of the light emitting display apparatus according to an embodiment of the present disclosure may control the first common power voltage EVSS1 to 0V, which is a low-potential power voltage, and may control the second common power voltage EVSS2 to 10V (or any other voltage level higher than that of the first common power voltage EVSS1, such as 2V, 8V, 12V, etc.) having a voltage level higher than that of the first common power voltage EVSS1. For example, the first common power voltage EVSS1 and the second common power voltage EVSS2 may be a low-potential power voltage having a voltage level lower than that of the first power voltage EVSS (or pixel power voltage) applied through the first power line (or pixel power line).

Referring to FIG. 5, the first common power line VSSL1 and the second common power line VSSL2 may extend in parallel to each other in the first direction (or Y-axis direction) of the display panel 110. At least one of the first common power line VSSL1 and the second common power line VSSL2 may be disposed to overlap at least a portion of the emission area of the plurality of subpixels SP1, SP2, SP3, and SP4. The first common power line VSSL1 and the second common power line VSSL2 may be disposed to be adjacent to each other on the right side or the left side in the second direction (or X-axis direction) of the plurality of subpixels SP1, SP2, SP3, and SP4. For example, as shown in FIG. 5, the first common power line VSSL1 and the second common power line VSSL2 may be disposed adjacent to each other on the left side in the second direction (or X-axis direction) of the plurality of subpixels SP1, SP2, SP3, and SP4.

The first common power line VSSL1 and the second common power line VSSL2 may be electrically connected to the common electrode CE of the light emitting element ED at different positions in the first direction (or Y-axis direction) of the display panel 110. The first common power line VSSL1 and the second common power line VSSL2 may be electrically connected to the common electrode CE of the light emitting element ED at a position where the first common power line VSSL1 and the second common power line VSSL2 may have different electrical distances to the first divided electrode PAE1 and the second divided electrode PAE2 of the first electrode AE. For example, the first common power line VSSL1 and the second common power line VSSL2 may be disposed adjacent to the first subpixel SP1 among the plurality of subpixels SP1, SP2, SP3, and SP4. For example, the first common power line VSSL1 may be disposed such that the cathode contact portion CT1 electrically connected to the common electrode CE is adjacent to the first divided electrode PAE1 of the first subpixel SP1. In addition, the second common power line VSSL2 may be disposed such that the cathode contact portion CT2 electrically connected to the common electrode CE is adjacent to the second divided electrode PAE2 of the first subpixel SP1. For example, a bridge connection pattern disposed on the different layer from the first common power line VSSL1 may be disposed between the second common power line VSSL2 and the cathode contact portion CT2.

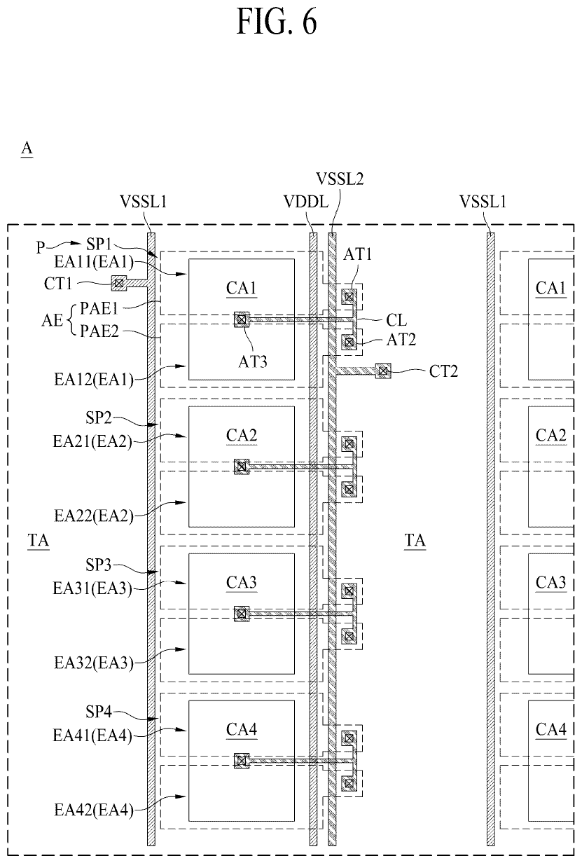

Referring to FIG. 6, the light emitting display apparatus according to an embodiment of the present disclosure may include the plurality of subpixels SP1, SP2, SP3, and SP4, a first power line (or pixel power line), a first common power line VSSL1, and a second common power line VSSL2.

The first common power line VSSL1 and the second common power line VSSL2 may extend in parallel to each other in the first direction (or Y-axis direction) of the display panel 110. The first common power line VSSL1 and the second common power line VSSL2 may be disposed on the right side and the left side in the second direction (or X-axis direction) of the plurality of subpixels SP1, SP2, SP3, and SP4. For example, as shown in FIG. 6, the first common power line VSSL1 may be disposed on the left side in the second direction (or X-axis direction) of the plurality of subpixels SP1, SP2, SP3, and SP4, and the second common power line VSSL2 may be disposed on the right side in the second direction (or X-axis direction) of the plurality of subpixels SP1, SP2, SP3, and SP4.

The first common power line VSSL1 and the second common power line VSSL2 may be disposed to overlap the emission areas EA1, EA2, EA3, and EA4 of the plurality of subpixels SP1, SP2, SP3, and SP4, or may be disposed to overlap the transmission area TA adjacent to the plurality of subpixels SP1, SP2, SP3, and SP4, or may be disposed to overlap a non-transmission area NTA except for the emission areas. For example, any one of the first common power line VSSL1 and the second common power line VSSL2 may be disposed to overlap the emission areas EA1, EA2, EA3, and EA4 of the plurality of subpixels SP1, SP2, SP3, and SP4, and the other of the first common power line VSSL1 and the second common power line VSSL2 may be disposed to overlap the transmission area TA adjacent to the plurality of subpixels SP1, SP2, SP3, and SP4 or the non-transmission area NTA.

The first common power line VSSL1 and the second common power line VSSL2 may be electrically connected to the common electrode CE of the light emitting element ED at the same position or different positions in the first direction (or Y-axis direction) of the display panel 110. The first common power line VSSL1 and the second common power line VSSL2 may be electrically connected to the common electrode CE of the light emitting element ED at a position where the first common power line VSSL1 and the second common power line VSSL2 may have different electrical distances to the first divided electrode PAE1 and the second divided electrode PAE2 of the first electrode AE. For example, the first common power line VSSL1 and the second common power line VSSL2 may be disposed adjacent to the first subpixel SP1 among the plurality of subpixels SP1, SP2, SP3, and SP4.

The first common power line VSSL1 may be disposed on the left side in the second direction (or X-axis direction) of the plurality of subpixels SP1, SP2, SP3, and SP4, and the first common power line VSSL1 may be disposed such that the cathode contact portion CT1 electrically connected to the common electrode CE is adjacent to the first divided electrode PAE1 of the first subpixel SP1.

The second common power line VSSL2 may be disposed on the right side in the second direction (or X-axis direction) of the plurality of subpixels SP1, SP2, SP3, and SP4, and the second common power line VSSL2 may be disposed such that the cathode contact portion CT2 electrically connected to the common electrode CE is adjacent to the second divided electrode PAE2 of the first subpixel SP1. For example, the second common power line VSSL2 may be disposed closer to the transmission area TA than the first power line VDDL, but embodiments of the present disclosure are not limited thereto. As an example, the first power line VDDL may be disposed closer to the transmission area TA than the second common power line VSSL2.

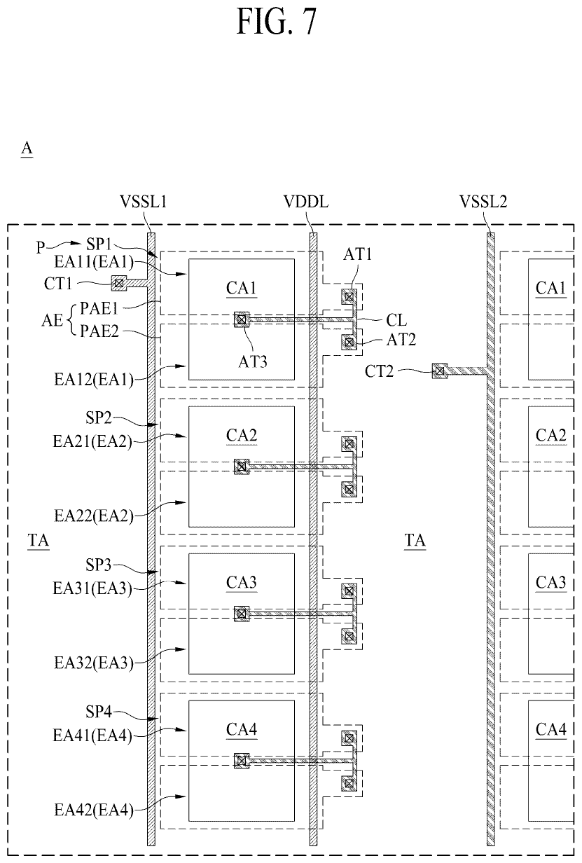

Referring to FIG. 7, the light emitting display apparatus according to an embodiment of the present disclosure may include the plurality of subpixels SP1, SP2, SP3, and SP4, a first power line (or pixel power line), a first common power line VSSL1, and a second common power line VSSL2.

The first common power line VSSL1 and the second common power line VSSL2 may extend in parallel to each other in the first direction (or Y-axis direction) of the display panel 110. The first common power line VSSL1 and the second common power line VSSL2 may be disposed on the right side and the left side in the second direction (or X-axis direction) of the plurality of subpixels SP1, SP2, SP3, and SP4. For example, as shown in FIG. 7, the first common power line VSSL1 may be disposed on the left side in the second direction (or X-axis direction) of the plurality of subpixels SP1, SP2, SP3, and SP4, and the second common power line VSSL2 may be disposed on the right side in the second direction (or X-axis direction) of the plurality of subpixels SP1, SP2, SP3, and SP4. The transmission area TA may be disposed between the second common power line VSSL2 and the plurality of subpixels SP1, SP2, SP3, and SP4. For example, the first common power line VSSL1 and the second common power line VSSL2 may be disposed in each of pixels including the plurality of subpixels SP1, SP2, SP3, and SP4 adjacent to each other in the second direction.

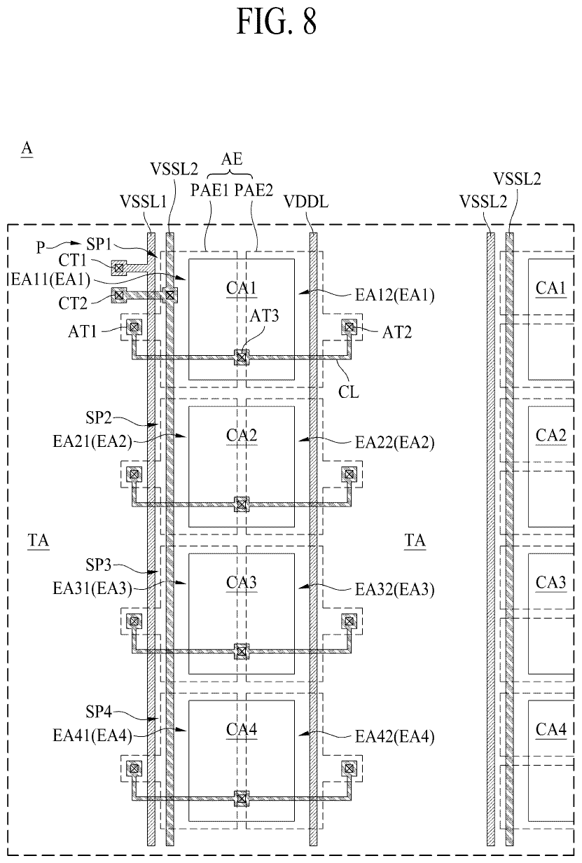

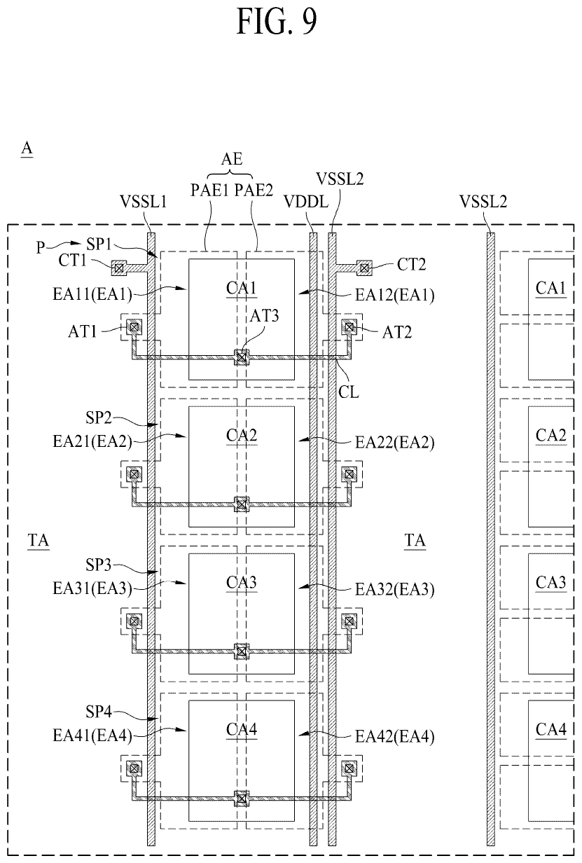

Referring to FIGS. 8 and 9, the light emitting display apparatus according to an embodiment of the present disclosure may include the plurality of subpixels SP1, SP2, SP3, and SP4, a first power line VDDL (or pixel power line), a first common power line VSSL1, and a second common power line VSSL2.

Each of the plurality of subpixels SP1, SP2, SP3, and SP4 may include a first divided electrode PAE1 (or first divided pixel electrode) and a second divided electrode PAE2 (or second divided pixel electrode) spaced apart from each other in the second direction (or X-axis direction). For example, the first divided electrode PAE1 and the second divided electrode PAE2 may be disposed adjacent to each other in the second direction.

The first emission area EA1 included in the first subpixel SP1 may include a first divided emission area EA1l and a second divided emission area EA12, and the first divided emission area EA1l and the second divided emission area EA12 may be disposed adjacent to each other in the second direction (or the X-axis direction). The second emission area EA2 included in the second subpixel SP2 may include a first divided emission area EA21 and a second divided emission area EA22, and the first divided emission area EA21 and the second divided emission area EA22 may be disposed adjacent to each other in the second direction (or the X-axis direction). The third emission area EA3 included in the third subpixel SP3 may include a first divided emission area EA31 and a second divided emission area EA32, and the first divided emission area EA31 and the second divided emission area EA32 may be disposed adjacent to each other in the second direction (or the X-axis direction). The fourth emission area EA4 included in the fourth subpixel SP4 may include a first divided emission area EA41 and a second divided emission area EA42, and the first divided emission area EA41 and the second divided emission area EA42 may be disposed adjacent to each other in the second direction (or X-axis direction).

Referring to FIGS. 8 and 9, the first divided electrode PAE1 and the second divided electrode PAE2 may be electrically connected to each other through a connection line CL. The connection line CL may serve to repair darkening in any one of the first and second divided electrodes PAE1 and PAE2. For example, the connection line CL may electrically connect the first divided electrode PAE1 and the second divided electrode PAE2 to the circuit area CA1, CA2, CA3, and CA4 of the subpixels SP1, SP2, SP3, and SP4. For example, the connection line CL may be configured in “1” shape or “C” shape, but embodiments of the present disclosure are not limited thereto. One end of the connection line CL may be electrically connected to the first divided electrode PAE1 through a first contact portion AT1, the other end of the connection line CL may be electrically connected to the second divided electrode PAE2 through a second contact portion AT2, and a point (e.g., the center, or any point other than the center) between one end and the other end of the connection line CL may be electrically connected to corresponding one of the circuit area CA1, CA2, CA3, and CA4 of the subpixels SP1, SP2, SP3, and SP4 through a third contact portion AT3.

When foreign substances are generated in any one of the first divided electrode PAE1 and the second divided electrode PAE2, the connection line CL may serve to separate or disconnect the electrical connection between the divided electrode in which the foreign substances are generated and the circuit areas CA1, CA2, CA3, and CA4, thereby darkening only the divided electrode in which the foreign substances are generated and repairing the remaining divided electrode to be normally operated. For example, the divided electrode, in which the foreign substances are generated, among the first divided electrode PAE1 and the second divided electrode PAE2 may be electrically separated or disconnected from the connection line CL, and the divided electrode without the foreign substances among the first divided electrode PAEL and the second divided electrode PAE2 may be electrically connected to the circuit areas CA1, CA2, CA3, and CA4 through the connection line CL.

Referring to FIGS. 8 and 9, the first power line VDDL may extend in the first direction (or Y-axis direction) of the display panel 110 and may be disposed on the right or left side in the second direction (or X-axis direction) of the plurality of subpixels SP1, SP2, SP3, and SP4. For example, the first power line VDDL may be disposed on the right side in the second direction (or X-axis direction) of the plurality of subpixels SP1, SP2, SP3, and SP4, but embodiments of the present disclosure are not limited thereto.

Referring to FIG. 8, the first common power line VSSL1 and the second common power line VSSL2 may extend in parallel to each other in the first direction (or Y-axis direction) of the display panel 110. The first common power line VSSL1 and the second common power line VSSL2 may be disposed in parallel to each other on the right side or left side in the second direction (or X-axis direction) of the plurality of subpixels SP1, SP2, SP3, and SP4. For example, the first common power line VSSL1 and the second common power line VSSL2 may be disposed on the left side in the second direction (or X-axis direction) of the plurality of subpixels SP1, SP2, SP3, and SP4.

The first common power line VSSL1 and the second common power line VSSL2 may be electrically connected to the common electrode CE of the light emitting element ED at different positions in the first direction (or Y-axis direction) of the display panel 110. The first common power line VSSL1 and the second common power line VSSL2 may be electrically connected to the common electrode CE of the light emitting element ED at a position where the first common power line VSSL1 and the second common power line VSSL2 may have different electrical distances to the first divided electrode PAE1 and the second divided electrode PAE2 of the first electrode AE. For example, the first common power line VSSL1 and the second common power line VSSL2 may be disposed adjacent to the first subpixel SP1 among the plurality of subpixels SP1, SP2, SP3, and SP4. For example, the cathode contact portions CT1 and CT2 of the first common power line VSSL1 and the second common power line VSSL2 may be disposed adjacent to the first divided electrode PAE1 of the first subpixel SP1, and may be disposed at different positions in the first direction (or Y-axis direction) of the display panel 110. For example, a bridge connection pattern disposed on the different layer from the first common power line VSSL1 may be disposed between the second common power line VSSL2 and the cathode contact portion CT2.

Referring to FIG. 9, the first common power line VSSL1 and the second common power line VSSL2 may extend in parallel to each other in the first direction (or Y-axis direction) of the display panel 110. The first common power line VSSL1 and the second common power line VSSL2 may be disposed on the right side and the left side in the second direction (or X-axis direction) of the plurality of subpixels SP1, SP2, SP3, and SP4. For example, the first common power line VSSL1 may be disposed on the left side in the second direction (or X-axis direction) of the plurality of subpixels SP1, SP2, SP3, and SP4, and the second common power line VSSL2 may be disposed on the right side in the second direction (or X-axis direction) of the plurality of subpixels SP1, SP2, SP3, and SP4. For example, the first common power line VSSL1 and the second common power line VSSL2 may be disposed adjacent to the first subpixel SP1 among the plurality of subpixels SP1, SP2, SP3, and SP4.

The first common power line VSSL1 may be disposed on the left side in the second direction (or X-axis direction) of the plurality of subpixels SP1, SP2, SP3, and SP4, and the first common power line VSSL1 may be disposed such that the cathode contact portion CT1 electrically connected to the common electrode CE is adjacent to the first divided electrode PAE1 of the first subpixel SP1.

The second common power line VSSL2 may be disposed on the right side in the second direction (or X-axis direction) of the plurality of subpixels SP1, SP2, SP3, and SP4, and the second common power line VSSL2 may be disposed such that the cathode contact portion CT2 electrically connected to the common electrode CE is adjacent to the second divided electrode PAE2 of the first subpixel SP1. For example, the second common power line VSSL2 may be disposed closer to the transmission area TA than the first power line VDDL, but embodiments of the present disclosure are not limited thereto.

In the light emitting display apparatus according to an embodiment of the present disclosure, the first divided electrode PAE1 and the second divided electrode PAE2 of the first electrode AE have the different electrical distances with respect to the first common power line VSSL1 and the second common power line VSSL2, and the first common power voltage EVSS1 and the second common power voltage EVSS2 having the different voltage levels are applied in common to the common electrode CE of the light emitting element ED through the first common power line VSSL1 and the second common power line VSSL2 so that it is possible to generate a resistance difference from the common electrode CE and the first and second common power lines VSSL1 and VSSL2 to the first and second divided electrodes PAE1 and PAE2. Accordingly, it is possible to detect a short circuit between one of the first divided electrode PAE1 and the second divided electrode PAE2 and the common electrode CE by using a change in the voltage measurement value of common node between the first divided electrode PAE1 and the second divided electrode PAE2. According to an embodiment of the present disclosure, it is possible to omit a process of observing foreign substances with naked eyes in a semi-dark repair process, to automatically detect a semi-dark repair target based on the voltage measurement value of common node between the first divided electrode PAE1 and the second divided electrode PAE2, which are changed by the voltage level difference between the first and second common power voltages EVSS1 and EVSS2, and to determine a micro short short by the foreign substances, thereby implementing or realizing the light emitting display apparatus having a repair structure capable of accurately detecting a semi-dark repair target.

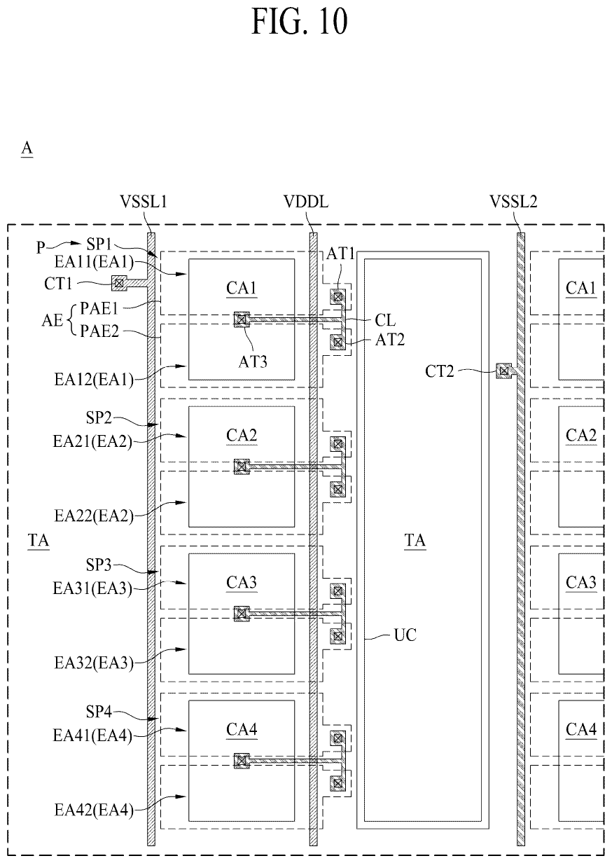

Referring to FIG. 10, the light emitting display apparatus according to an embodiment of the present disclosure may include the plurality of subpixels SP1, SP2, SP3, and SP4, a first power line (or pixel power line), a first common power line VSSL1, a second common power line VSSL2, and an undercut structure UC.

The undercut structure UC may be configured to surround the edge of transmission area. For example, the undercut structure UC may be configured to disconnect the common electrode CE in the transmission area TA and the common electrode CE disposed in the emission area EA1, EA2, EA3, and EA4. The first common power line VSSL1 and the second common power line VSSL2 may be disposed not to overlap the undercut structure UC. For example, the undercut structure UC may be disposed between the first common power line VSSL1 and the second common power line VSSL2. For example, the undercut structure UC may be disposed between the plurality of subpixels SP1, SP2, SP3, and SP4 and the first common power line VSSL1. For example, the undercut structure UC may be disposed between the plurality of subpixels SP1, SP2, SP3, and SP4 and the second common power line VSSL2.

Referring to FIG. 11, the light emitting display apparatus according to an embodiment of the present disclosure may further include a repair detecting part 500 electrically connected to a second node N2, which is a common node between a first divided electrode PAE1 (or first divided pixel electrode) and a second divided electrode PAE2 (or second divided pixel electrode) of a light emitting element ED.

In the light emitting display apparatus according to an embodiment of the present disclosure, a first electrode AE of the light emitting element ED may be divided into the first divided electrode PAE1 and the second divided electrode PAE2 and may be configured with a first partial light emitting element PED1 and a second partial light emitting element PED2, and an emission layer EL and a second electrode CE may be commonly included in the first partial light emitting element PED1 and the second partial light emitting element PED2. Also, the first common power line VSSL1 and the second common power line VSSL2 may apply first and second common power voltages EVSS1 and EVSS2 to the second electrode CE included in the first partial light emitting element PED1 and the second partial light emitting element PED2.

The repair detecting part 500 may detect a short circuit between one of the first divided electrode PAE1 and the second divided electrode PAE2 and the common electrode CE based on a voltage measurement value of the second node N2 (or common node). For example, the repair detecting part 500 may detect whether any one of the first divided light emitting element PED1 including the first divided electrode PAE1 and the second divided light emitting element PED2 including the second divided electrode PAE2 is defective. The repair detecting part 500 may be included in the data driver 130. For example, the repair detecting part 500 may be embedded in the data drive IC 131 of the data driver 130. Embodiments are not limited thereto. As an example, the repair detecting part 500 may be separated from the data driver 130. As an example, the repair detecting part 500 may be disposed at the non-display area NDA or be attached to the non-display area NDA, without being limited thereto. As an example, the repair detecting part 500 may be connected to the reference line REFL, without being limited thereto.

The repair detecting part 500 may include a sensing part 510 for measuring the voltage of the reference line REFL, and a sampling switch SAM electrically connected between the reference line REFL and the sensing part 510. For example, the sensing part 510 may be implemented as an analog-to-digital converter ADC.

The repair detecting part 500 may further include a detecting part 520 for detecting whether any one defect (or short circuit) in any one of the first divided light emitting element PED1 or first divided electrode PAE1 and the second divided light emitting element PED2 or second divided electrode PAE2 is generated based on the voltage measurement value measured by the sensing part 510, and a memory 530 for storing the detection result of the detecting part 520 and information related thereto.

The repair detecting part 500 (or the power circuit 170, or any other component) may simultaneously apply the first common power voltage EVSS1 and the second common power voltage EVSS2 having different voltage levels to the second electrode CE of the light emitting element ED, and the repair detecting part 500 may measure the voltage transferred to the second node N2 (or common node) between the first divided electrode PAE1 and the second divided electrode AE2 through the second electrode CE, and may detect whether any one defect (or short circuit) in the first divided light emitting element PED1 or first divided electrode PAE1 and the second divided light emitting element PED2 or second divided electrode PAE2 is generated based on the voltage measurement value of the second node N2.

According to an embodiment of the present disclosure, the first and second divided electrodes PAE1 and PAE2 of the first electrode AE may have different electrical distances with respect to the first common power line VSSL1 and the second common power line VSSL2, and the first common power voltage EVSS1 and the second common power voltage EVSS2 having different voltage levels are applied in common to the common electrode CE of the light emitting element ED through the first common power line VSSL1 and the second common power line VSSL2 so that it is possible to generate a resistance difference from the common electrode CE and the first and second common power lines VSSL1 and VSSL2 to the first and second divided electrodes PAE1 and PAE2. For example, resistors R1, R2, R3, and R4 may be formed between the light emitting element ED and the first and second common power lines VSSL1 and VSSL2. The resistors R1, R2, R3, and R4 may be changed according to the relative electrical distance between the first and second divided electrodes PAE1 and PAE2 and the first and second common power lines VSSL1 and VSSL2. For example, the electrical distance between the first divided electrode PAE1 and the first common power line VSSL1 may correspond to the electrical distance between a portion CE1 of the common electrode overlapping the first divided electrode PAE1 and the first common power line VSSL1, and the electrical distance between the second divided electrode PAE2 and the second common power line VSSL2 may correspond to the electrical distance between a portion CE2 of the common electrode overlapping the second divided electrode PAE2 and the second common power line VSSL2. For example, the resistor R1 may be a resistance between the first common power line VSSL1 and the first divided electrode PAE1. For example, the resistor R1 may be a resistance from the cathode contact portion CT1 at which the first common power line VSSL1 is electrically connected to the common electrode CE to the portion CE1 of the common electrode overlapping the first divided electrode PAE1. The resistor R2 may be a resistance between the second common power line VSSL2 and the second divided electrode PAE2. For example, the resistor R2 may be a resistance from the cathode contact portion CT2 at which the second common power line VSSL2 is electrically connected to the common electrode CE to the portion CE2 of the common electrode overlapping the second divided electrode PAE2. The resistor R3 may be a resistance between the first divided electrode PAE1 and the second divided electrode PAE2. For example, the resistor R3 may be a resistance between the portion CE1 of the common electrode overlapping the first divided electrode PAE1 and the portion CE2 of the common electrode overlapping the second divided electrode PAE2. The resistor R4 may be a resistance between the first common power line VSSL1 and the second common power line VSSL2. For example, the resistor R4 may be a resistance from the cathode contact portion CT1 at which the first common power line VSSL1 is electrically connected to the common electrode CE to the cathode contact portion CT2 at which the second common power line VSSL2 is electrically connected to the common electrode CE.

The repair detecting part 500 may detect a defect (or short circuit) in any one of the first divided light emitting element PED1 or first divided electrode PAE1 and the second divided light emitting element PED2 or second divided electrode PAE2 based on the voltage measurement value of second node (or common node) N2 between the first divided electrode PAE1 and the second divided electrode PAE2 changed by the first common power voltage EVSS1 and the second common power voltage EVSS2 applied with different voltage levels through the use of resistance difference.

The repair detecting part 500 may measure the voltage of the second node N2 under the condition that the driving transistor DR and the first switching transistor TR1 are turned-off and the second switching transistor TR2 is turned-on, and may detect whether any one defect (or short circuit) in any one of the first divided light emitting element PEI or first divided electrode PAE1 and the second divided light emitting element PED2 or second divided electrode PAE2 occurs.

Referring to FIG. 12, under the condition that the first common power voltage EVSS1 is applied as 0V and the second common power voltage EVSS2 is applied as 10V, the voltage measurement value of the second node N2 detected through the repair detecting part 500 may be detected as 10V when a defect does not occur in both the first divided light emitting element PED1 or first divided electrode PAE1 and the second divided light emitting element PED2 or second divided electrode PAE2. Also, when a defect occurs in any one of the first divided light emitting element PED1 or first divided electrode PAE1 and the second divided light emitting element PED2 or second divided electrode PAE2, the voltage measurement value of the second node N2 detected through the repair detecting part 500 may be detected to be 5V or more or 5V or less according to the position at which the defect occurs with respect to 5V. For example, when foreign substances are generated in the portion CE1 of the common electrode overlapping the first divided light emitting element PED1 or first divided electrode PAE1, the resistance R1 between the portion CE1 of the common electrode overlapping the first divided electrode PAE1 and any one of the first and second common power lines VSSL1 and VSSL2 may be changed, whereby the voltage measurement value of the second node N2 detected through the repair detecting part 500 may be detected to be 5V or less by the influence of the changed resistance R1. In addition, when foreign substances are generated in the portion CE2 of the common electrode overlapping the second divided light emitting element PED2 or second divided electrode PAE2, the resistance R2 between the portion CE2 of the common electrode overlapping the second divided electrode PAE2 and one of the first and second common power lines VSSL1 and VSSL2 may be changed, whereby the voltage measurement value of the second node N2 detected through the repair detecting part 500 may be detected to be 5V or more by the changed influence of the resistance R2. Accordingly, the repair detecting part 500 may set a base line BL, which is a reference for determining whether the defect occurs, to 5V, but embodiments of the present disclosure are not limited thereto.

When the defect (or short circuit) occurs in the first divided light emitting element PED1 or first divided electrode PAE1, the repair detecting part 500 may detect the voltage measurement value of the second node N2 as a voltage of 5V which is the base line BL or less. Accordingly, the repair detecting part 500 may determine that the defect (or short circuit) occurs in the first divided light emitting element PED1 or first divided electrode PAE1.

When the defect (or short circuit) occurs in the second divided light emitting element PED2 or second divided electrode PAE2, the repair detecting part 500 may detect the voltage measurement value of the second node N2 as a voltage of 5V which is the base line BL or more. Accordingly, the repair detecting part 500 may determine that the defect (or short circuit) occurs in the second divided light emitting element PED2 or second divided electrode PAE2.

Referring to FIG. 13, the light emitting display apparatus according to another embodiment of the present disclosure may further include a repair detecting part 500 electrically connected to a second node N2 corresponding to a common node between a first divided electrode PAE1 (or first divided pixel electrode) and a second divided electrode PAE2 (or second divided pixel electrode) of a light emitting element ED.

In the light emitting display apparatus according to another embodiment of the present disclosure, a first electrode AE of the light emitting element ED may be divided into the first divided electrode PAE1 and the second divided electrode PAE2 and may be configured with a first partial light emitting element PED1 and a second partial light emitting element PED2, a second electrode CE may be configured with a first common electrode PCE1 and a second common electrode PCE2 to correspond to the first and second divided electrodes PAE1 and PAE2, respectively, and the first common electrode PCE1 may be included in the first partial light emitting element PED1, and the second common electrode PCE2 may be included in the second partial light emitting element PED2. In addition, a first common power line VSSL1 may apply a first common power voltage EVSS1 to the first common electrode PCE1 corresponding to the first divided electrode PAE1, and a second common power line VSSL2 may apply a second common power voltage EVSS2 to the second common electrode PCE2 corresponding to the second divided electrode PAE2.

The repair detecting part 500 (or the power circuit 170) may simultaneously apply the first common power voltage EVSS1 and the second common power voltage EVSS2 having different voltage levels to the first common electrode PCE1 and the second common electrode PCE2, respectively, of the light emitting element ED, and the repair detecting part 500 may measure a voltage transferred to the second node N2 (or common node) between the first divided electrode PAE1 and the second divided electrode PAE2 through the first common electrode PCE1 and the second common electrode PCE2, and may detect whether a defect (or short circuit) in any one of the first divided light emitting element PED1 or first divided electrode PAE1 and the second divided light emitting element PED2 or second divided electrode PAE2 occurs, based on the voltage measurement value of the second node N2.

According to another embodiment of the present disclosure, the first and second divided electrodes PAE1 and PAE2 of the first electrode AE may have different electrical distances with respect to the first common power line VSSL1 and the second common power line VSSL2, the first common power voltage EVSS1 may be applied to the first common electrode PCE1 corresponding to the first divided electrode PAE1 through the first common power line VSSL1, and the second common power voltage EVSS2 may be applied to the second common electrode PCE2 corresponding to the second divided electrode PAE2 through the second common power line VSSL2 so that it is possible to generate a resistance difference between the first common electrode PCE1, first common power line VSSL1 and first divided electrode PAE1 and the second common electrode PCE2, second common power line VSSL2 and second divided electrode PAE2. For example, resistances R1 and R2 may be formed between the light emitting element ED and the first and second common power lines VSSL1 and VSSL2. The resistances R1 and R2 may be changed according to the relative electrical distance between the first and second divided electrodes PAE1 and PAE2 and the first and second common power lines VSSL1 and VSSL2. For example, the resistance R1 may be the resistance between the first common electrode PCE1 and the first common power line VSSL1. For example, the resistance R1 may be the resistance from the cathode contact portion CT1 at which the first common power line VSSL1 is electrically connected to the common electrode CE to the first common electrode PCE1 overlapping the first divided electrode PAE1. The resistance R2 may be the resistance between the second common electrode PCE2 and the second common power line VSSL2. For example, the resistance R2 may be the resistance from the cathode contact portion CT2 at which the second common power line VSSL2 is electrically connected to the common electrode CE to the second common electrode PCE2 overlapping the second divided electrode PAE2.

The repair detecting part 500 may detect a defect (or short circuit) in any one of the first divided light emitting element PED1 or first divided electrode PAE1 and the second divided light emitting element PED2 or second divided electrode PAE2 based on the voltage measurement value of second node (or common node) N2 between the first divided electrode PAE1 and the second divided electrode PAE2 changed by the first common power voltage EVSS1 and the second common power voltage EVSS2 applied with different voltage levels through the use of resistance difference.

Referring to FIG. 14, under the condition that the first common power voltage EVSS1 is applied as 0V and the second common power voltage EVSS2 is applied as 10V, the voltage measurement value of the second node N2 detected through the repair detecting part 500 may be detected as 10V when the defect does not occur in both the first divided light emitting element PED1 or first divided electrode PAE1 and the second divided light emitting element PED2 or second divided electrode PAE2. Also, when the defect occurs in any one of the first divided light emitting element PED1 or first divided electrode PAE1 and the second divided light emitting element PED2 or second divided electrode PAE2, the voltage measurement value of the second node N2 detected through the repair detecting part 500 may be detected between 10V and 5V or between 5V and 0V according to the position at which the defect occurs with respect to 5V. For example, a voltage adjacent to 0V may be detected when the defect occurs in the first divided light emitting element PED1 or first divided electrode PAE1, and a voltage adjacent to 10V may be detected when the defect occurs in the second divided light emitting element PED2 or second divided electrode PAE2, but embodiments of the present disclosure are not limited thereto.

When the defect (or short circuit) occurs in the first divided light emitting element PED1 or first divided electrode PAE1, the repair detecting part 500 may detect the voltage measurement value of the second node N2 to be 5V which is the base line BL or less, and it may be detected as the voltage adjacent to 0V. Accordingly, the repair detecting part 500 may determine that the defect (or short circuit) occurs in the first divided light emitting element PED1 or first divided electrode PAE1.

When the defect (or short circuit) occurs in the second divided light emitting element PED2 or second divided electrode PAE2, the repair detecting part 500 may detect a voltage measurement value of the second node N2 to be 5V which is the base line BL or more, and it may be detected as the voltage adjacent to 10V. Accordingly, the repair detecting part 500 may determine that the defect (or short circuit) occurs in the second divided light emitting element PED2 or second divided electrode PAE2.

FIG. 15 illustrates a light emitting display apparatus according to another embodiment of the present disclosure.

Referring to FIG. 15, a display panel 110 of the light emitting display apparatus according to another embodiment of the present disclosure may include a display area DA in which pixels are configured to display an image and a non-display area NDA which does not display an image. For example, the non-display area NDA may be disposed in the periphery of the display area DA.

The non-display area NDA of the display panel 110 according to another embodiment of the present disclosure may include a pad area PA in which pads to be applied with an external signal are disposed, and a plurality of scan drivers 120a and 120b. Also, the display panel 110 may include a non-pad area NPA disposed in the non-display area NDA confronting the pad area PA with the display area DA interposed therebetween. For example, the non-pad area NPA may be disposed in an area opposite to the pad area PA in the non-display area NDA of the display panel 110. The non-pad area NPA may be an area in which pads are not disposed. Embodiments are not limited thereto. As an example, there may be no non-pad area NPA confronting the pad area PA. On the contrary, the pad area PA may be disposed on both sides of the display area DA.

The display panel 110 may include a source drive integrated circuit (hereinafter, referred to as “source drive IC”) 131, a flexible film 140, a circuit board 150, and a timing controller 160.

At least one common power shorting bar SB1 and SB2 may be disposed in the non-display area NDA of the display panel 110. The at least one common power shorting bar SB1 and SB2 may be disposed to extend in the second direction (or X-axis direction) in the pad area PA of the non-display area NDA. For example, the at least one common power shorting bar SB1 and SB2 may be electrically connected to a first common power line VSSL1 and a second common power line VSSL2 disposed on the display panel 110, respectively.

The at least one common power shorting bar SB1 and SB2 may include a first common power shorting bar SB1 connected to the first common power line VSSL1 and a second common power shorting bar SB2 connected to the second common power line VSSL2. The first common power shorting bar SB1 and the second common power shorting bar SB2 may be spaced apart from each other. For example, the first common power shorting bar SB1 and the second common power shorting bar SB2 may be spaced apart from each other in the first direction (or Y-axis direction). For example, the first common power shorting bar SB may be disposed closer to the display area DA than the second common power shorting bar SB2. For example, the second common power shorting bar SB2 may be disposed closer to the pad area PA than the first common power shorting bar SB1. Embodiments are not limited thereto. As an example, the second common power shorting bar SB2 may be disposed closer to the display area DA than the first common power shorting bar SB.

The first common power shorting bar SB1 and the second common power shorting bar SB2 may be electrically separated from each other. For example, the first common power shorting bar SB1 and the second common power shorting bar SB2 may be disposed on the same layer or different layers in the pad area PA. For example, the first common power line VSSL1 connected to the first common power shorting bar SB1 and the second common power line VSSL2 connected to the second common power shorting bar SB2 may be disposed on the same layer in the display area DA or may be disposed on different layers from each other in the display area DA.

The first common power line VSSL1 and the second common power line VSSL2 may be disposed on different layers in the non-display area NDA. For example, the first common power line VSSL1 and the second common power line VSSL2 may be disposed on different layers in the pad area PA. For example, the first common power line VSSL1 and the first common power shorting bar SB1 may be disposed on the same layer. In addition, the second common power line VSSL2 and the second common power shorting bar SB2 may be disposed on the same layer and may be disposed on the different layer from the first common power line VSSL1 and the first common power shorting bar SB1. The second common power line VSSL2 connected to the second common power shorting bar SB2 may intersect and overlap the first common power shorting bar SB1.

The first common power line VSSL1 and the second common power line VSSL2 may be disposed on the same layer in the non-display area NDA. For example, the first common power line VSSL1 and the second common power line VSSL2 may be disposed on the same layer in the pad area PA. For example, the first common power shorting bar SB1 and the second common power shorting bar SB2 may be disposed on the same layer and may be disposed on the different layer from the first common power line VSSL1 and the second common power line VSSL2. At least a portion of the first common power line VSSL1 may intersect and overlap the first common power shorting bar SB1 and may be electrically connected to the first common power shorting bar SB1 through a contact hole. Also, at least another portion of the first common power line VSSL1 may intersect and overlap the first common power shorting bar SB1 and the second common power shorting bar SB2 and may be electrically connected to the first common power shorting bar SB1 through a contact hole. In addition, the second common power line VSSL2 may intersect and overlap the first common power shorting bar SB1 and the second common power shorting bar SB2 and may be electrically connected to the second common power shorting bar SB2 through a contact hole.

The first common power shorting bar SB1 and the first common power line VSSL1 may be disposed on the same layer in the pad area PA or may be disposed on different layers from each other in the pad area PA. In addition, the second common power shorting bar SB2 and the second common power line VSSL2 may be disposed on the same layer in the pad area PA or may be disposed on different layers from each other in the pad area PA. For example, when the first and second common power shorting bars SB1 and SB2 and the first and second common power lines VSSL1 and VSSL2 are disposed on different layers, a bridge connection pattern for an electrical connection may be further included between the first and second common power shorting bars SB1 and SB2 and the first and second common power lines VSSL1 and VSSL2.

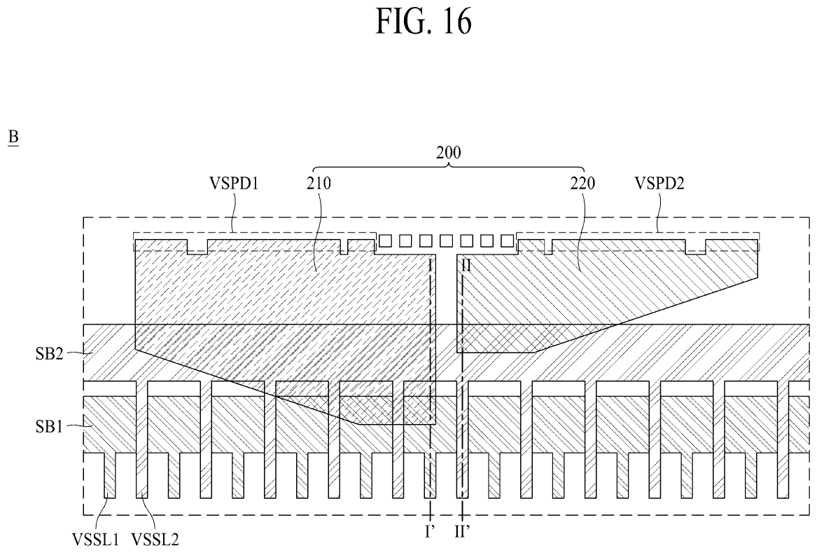

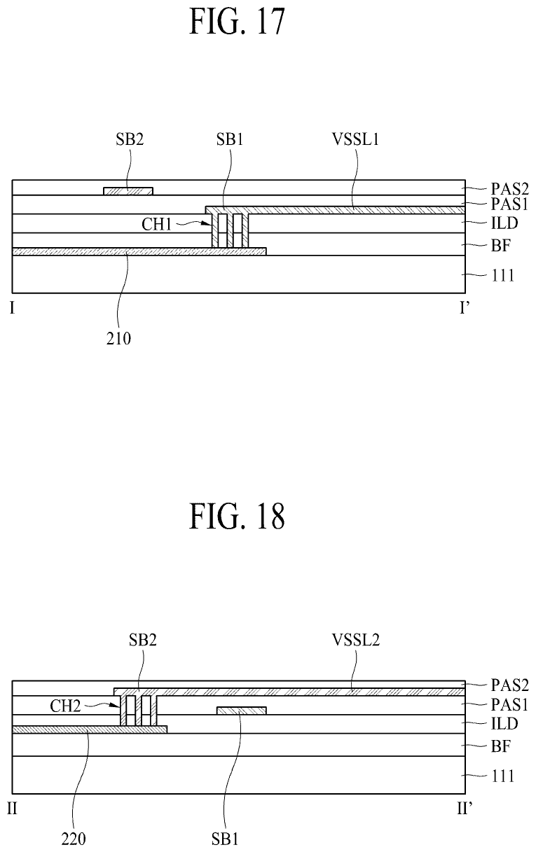

FIG. 16 illustrates a region B shown in FIG. 15 according to another embodiment of the present disclosure. FIG. 17 is a cross-sectional view taken along line I-I′ of FIG. 16 according to another embodiment of the present disclosure. FIG. 18 is a cross-sectional view taken along line II-II′ of FIG. 16 according to another embodiment of the present disclosure.

Referring to FIGS. 16 to 18 in connection with FIG. 15, the display panel 110 of the light emitting display apparatus according to another embodiment of the present disclosure may include a power pad portion 200 for applying first common power voltage and the second common power voltage to at least one common power shorting bar SB1 and SB2.

The display panel 110 may include a substrate 111 including a display area DA and a non-display area NDA. The non-display area NDA of the display panel 110 may include a pad area PA in which pads applied with an external signal are disposed. In addition, the non-display area NDA of the display panel 110 may include a non-pad area NPA confronting the pad area PA with the display area DA interposed therebetween.

In the pad area PA of the display panel 110, a first common power voltage pad VSPD1 to which the first common power voltage is applied and a second common power voltage pad VSPD2 to which the second common power voltage is applied may be disposed. The first and second common power voltage pads VSPD1 and VSPD2 may be electrically connected to the flexible film 140 via an anisotropic conducting film and may be connected to the plurality of data drive ICs 131. For example, the first common power voltage pad VSPD1 and the second common power voltage pad VSPD2 may be connected to the plurality of data drive ICs 131, respectively. For example, the first common power voltage pad VSPD1 and the second common power voltage pad VSPD2 may be connected to the different data drive ICs 131 among the plurality of data drive ICs 131. For example, the first common power voltage pad VSPD1 may be connected to the left-sided data drive IC 131 in the two adjacent data drive ICs 131, and the second common power voltage pad VSP2 may be connected to the right-sided data drive IC 131 in the two adjacent data drive ICs 131, but embodiments of the present disclosure are not limited thereto.

The power pad portion 200 may be electrically connected to the first common power voltage pad VSPD1 and the second common power voltage pad VSPD2 disposed in the pad area PA. The power pad portion 200 may include a first power pad portion 210 and a second power pad portion 220. For example, the first power pad portion 210 may be configured to connect the first common power voltage pad VSPD1 to which the first common power voltage is applied and the first common power shorting bar SB1. For example, the second power pad portion 220 may be configured to connect the second common power voltage pad VSPD2 to which the second common power voltage is applied and the second common power shorting bar SB2.

The first power pad portion 210 and the second power pad portion 220 may be disposed adjacent to each other in the pad area PA. For example, the first power pad portion 210 and the second power pad portion 220 may be disposed adjacent to each other in the second 220 may be spaced apart from each other in the second direction (or X-axis direction). Each of the first power pad portion 210 and the second power pad portion 220 may be configured in the form of straight line parallel to each other. At least a portion of opposite sides of each of the first power pad portion 210 and the second power pad portion 220 may be inclined. As an example, the sides of the first power pad portion 210 and the second power pad portion 220 facing with each other may have a form of straight line, and may be parallel with each other. As an example, the sides of the first power pad portion 210 and the second power pad portion 220 facing away from each other may be inclined. As an example, the widths of the first power pad portion 210 and the second power pad portion 220 may be increased from the pad area PA to the display area DA. Embodiments are not limited thereto. As an example, all sides of the first power pad portion 210 and the second power pad portion 220 may have the straight-line shape or the inclined shape.

One side of the first power pad portion 210 may be connected to the first common power voltage pad VSPD1, and the other side of the first power pad portion 210 may extend in the first direction (or Y-axis direction) to be connected to the first common power shorting bar SB1. For example, the first power pad portion 210 may be configured to be longer than or may be equal to or smaller than the second power pad portion 220 in the first direction (or Y-axis direction). For example, as shown in FIG. 17, the first power pad portion 210 may be disposed on the substrate 111. A buffer layer BF, an interlayer insulating layer ILD, a first passivation layer PAS1, and a second passivation layer PAS2 may be disposed on the first power pad portion 210, but embodiments of the present disclosure are not limited thereto. The first power pad portion 210 may overlap the first common power shorting bar SB1 and the second common power shorting bar SB2. For example, the first power shorting bar SB1 may be disposed on the interlayer insulating layer ILD, and the second power shorting bar SB2 may be disposed on the first passivation layer PAS1. The first power pad portion 210 may cross the second common power shorting bar SB2 and may be connected to the first common power shorting bar SB1. For example, the first power pad portion 210 may be connected to the first common power shorting bar SB1 through a first contact hole CH1 passing through the buffer layer BF and the interlayer insulating layer ILD. The first common power shorting bar SB1 may be disposed on the same layer as the first common power line VSSL1. For example, the first common power shorting bar SB1 and the first common power line VSSL1 may be integrally formed on the interlayer insulating layer ILD. For example, the first common power shorting bar SB1 may extend in the second direction (or X-axis direction) on the interlayer insulating layer ILD, and the first common power line VSSL1 may extend from the first common power shorting bar SB1 in the first direction (or Y-axis direction).

One side of the second power pad portion 220 may be connected to the second common power voltage pad VSPD2, and the other side of the second power pad portion 220 may extend in the first direction (or Y-axis direction) to be connected to the second common power shorting bar SB2. For example, the second power pad portion 220 may be configured to be shorter than the first power pad portion 210 in the first direction (or Y-axis direction). For example, as shown in FIG. 18, the second power pad portion 220 may be disposed on the buffer layer BF. The interlayer insulating layer ILD, the first passivation layer PAS1, and the second passivation layer PAS2 may be disposed on the second power pad portion 220, but embodiments of the present disclosure are not limited thereto. The second power pad portion 220 may not overlap the first common power shorting bar SB1 but may overlap the second common power shorting bar SB2. For example, the second common power shorting bar SB2 may be disposed on the first passivation layer PAS1. The second power pad portion 220 may be connected to the second common power shorting bar SB2. For example, the second power pad portion 220 may be connected to the second common power shorting bar SB2 through a second contact hole CH2 passing through the interlayer insulating layer ILD and the first passivation layer PAS1. The second common power shorting bar SB2 may be disposed on the same layer as the second common power line VSSL2. For example, the second common power shorting bar SB2 and the second common power line VSSL2 may be integrally formed on the first passivation layer PAS1. For example, the second common power shorting bar SB2 may extend in the second direction (or X-axis direction) on the first passivation layer PAS1, and the second common power line VSSL2 may extend from the second common power shorting bar SB2 in the first direction (or Y-axis direction). The second common power line VSSL2 may intersect and overlap the first common power shorting bar SB1 with the first passivation layer PAS1 interposed therebetween.

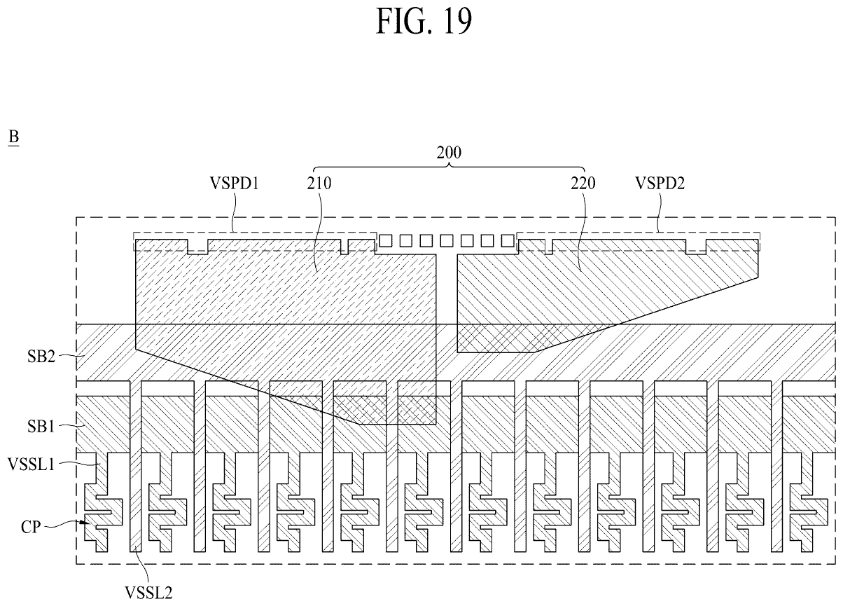

FIG. 19 illustrates a region B shown in FIG. 15 according to another embodiment of the present disclosure. FIG. 19 additionally configures a compensation pattern in the light emitting display apparatus described with reference to FIGS. 15 to 18. Accordingly, in the description of FIG. 19, the remaining components except for the compensation pattern and the configuration related thereto are designated by the same reference numerals, and a redundant description thereof will be omitted or simplified.

Referring to FIG. 19, the display panel 110 of the light emitting display apparatus according to another embodiment of the present disclosure may further include the compensation pattern CP based on the electrical distance difference between the first common power line VSSL1 and the second common power line VSSL2.

The first common power shorting bar SB1 and the second common power shorting bar SB2 may be spaced apart from each other in the first direction (or Y-axis direction). For example, the first common power shorting bar SB1 may be disposed closer to the display area DA than the second common power shorting bar SB2. For example, the second common power shorting bar SB2 may be disposed closer to the pad area PA than the first common power shorting bar SB1. Accordingly, the first common power line VSSL1 connected to the first common power shorting bar SB1 and the second common power line VSSL2 connected to the second common power shorting bar SB2 may have different electrical distances from each other. For example, the second common power line VSSL2 connected to the second common power shorting bar SB2 may have a longer length than the first common power line VSSL1 connected to the first common power shorting bar SB1, and the first common power line VSSL1 may be configured with the compensation pattern CP based on the electrical distance difference with the second common power line VSSL2. For example, the electrical distance difference may be a resistance deviation between the first common power line VSSL1 and the second common power line VSSL2.

The compensation pattern CP may be configured to compensate for the electrical distance difference between the first common power line VSSL1 and the second common power line VSSL2. For example, the compensation pattern CP may be configured to compensate for the resistance deviation between the first common power line VSSL1 and the second common power line VSSL2. For example, the compensation pattern CP may be configured to extend the electrical distance of the first common power line VSSL1. The compensation pattern CP may be configured to extend the electrical distance of the first common power line VSSL1 by the difference between the electrical distance of the first common power line VSSL1 and the electrical distance of the second common power line VSSL2. For example, the compensation pattern CP may be configured in a zigzag shape in a portion of the first common power line VSSL1, but embodiments of the present disclosure are not limited thereto.

According to another embodiment of the present disclosure, the compensation pattern CP is configured to compensate for the resistance deviation between the first common power line VSSL1 and the second common power line VSSL2 divided into the two so that it is possible to implement or realize the light emitting display apparatus capable of further improving the detection reliability of semi-dark repair target based on the first and second common power voltages applied through the first common power line VSSL1 and the second common power line VSSL2.

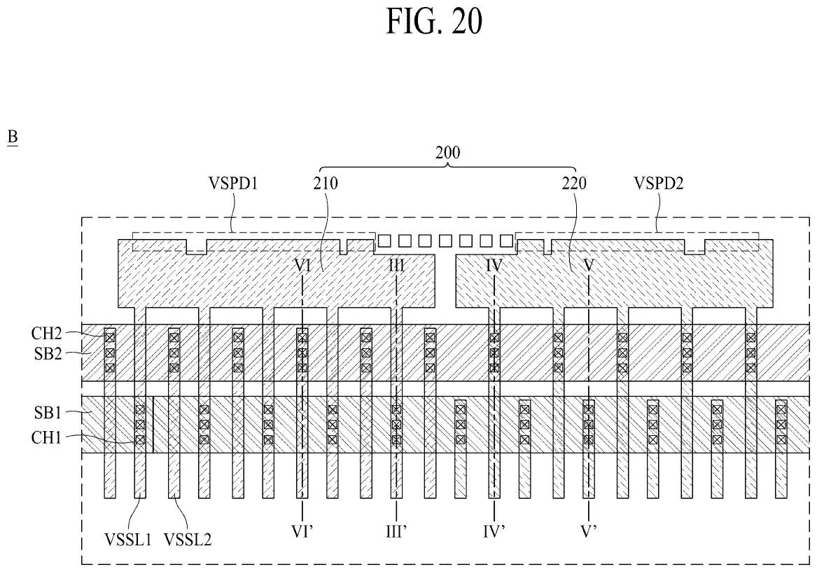

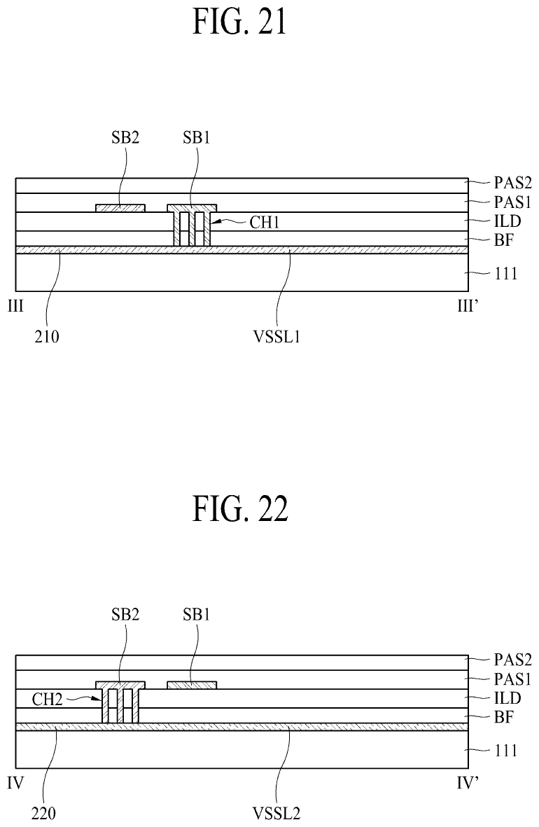

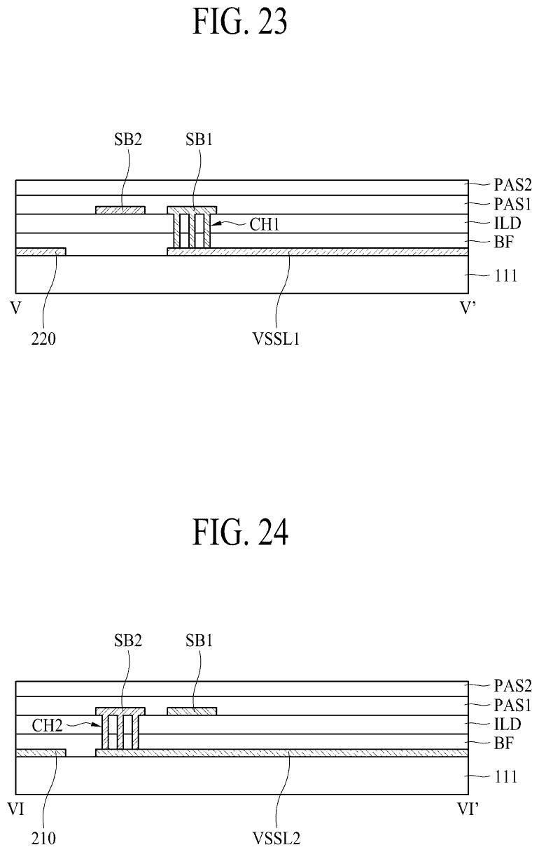

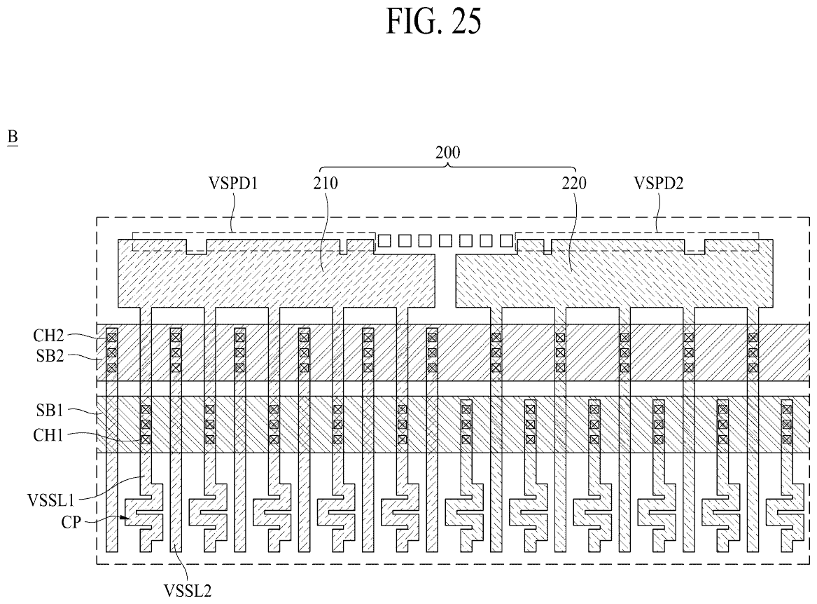

FIG. 20 illustrates a region B shown in FIG. 15 according to another embodiment of the present disclosure. FIG. 21 is a cross-sectional view taken along line III-III′ of FIG. 20 according to another embodiment of the present disclosure. FIG. 22 is a cross-sectional view taken along line IV-IV′ of FIG. 20 according to another embodiment of the present disclosure. FIG. 23 is a cross-sectional view taken along line V-V′ shown in FIG. 20 according to another embodiment of the present disclosure. FIG. 24 is a cross-sectional view taken along line VI-VI′ of FIG. 20 according to another embodiment of the present disclosure.

FIGS. 20 to 24 illustrate configurations obtained by changing of a power pad portion, first and second common power shorting bars, and first and second common power lines in the light emitting display apparatus described with reference to FIGS. 15 to 19. Accordingly, in the description of FIGS. 20 to 24, the same reference numerals are assigned to the remaining components except for the changed configuration, and a redundant description thereof will be omitted or simplified.

Referring to FIGS. 20 to 24 in connection with FIG. 15, the display panel 110 of the light emitting display apparatus according to another embodiment of the present disclosure may include the power pad portion 200 for applying the first common power voltage and the second common power voltage to at least one shorting bar SB1 and SB2.

The power pad portion 200 may be electrically connected to the first common power voltage pad VSPD1 and the second common power voltage pad VSPD2 disposed in the pad area PA. The power pad portion 200 may include a first power pad portion 210 and a second power pad portion 220. The first power pad portion 210 and the second power pad portion 220 may be disposed on the same layer in the pad area PA.

The first power pad portion 210 and the second power pad portion 220 may be disposed adjacent to each other in the pad area PA. For example, the first power pad portion 210 and the second power pad portion 220 may be disposed adjacent to each other in the second 220 may be spaced apart from each other in the second direction (or X-axis direction). The first power pad portion 210 and the second power pad portion 220 may be configured in the same shape. For example, the first power pad portion 210 and the second power pad portion 220 may be configured to be symmetrical in shape to each other.

One side of the first power pad portion 210 may be connected to the first common power voltage pad VSPD1. At least one first common power line VSSL1 may be connected to the other side of the first power pad portion 210. For example, the one or more first common power lines VSSL1 may extend from the other side of the first power pad portion 210 in the first direction (or Y-axis direction). The one or more first common power lines VSSL1 to be extended from the first power pad portion 210 may be electrically connected to the first common power shorting bar SB1 through a first contact hole CH1. For example, the plurality of first common power lines VSSL1 may be configured such that, at least a portion of the first common power line VSSL1 may be configured to extend from the first power pad portion 210, and at least another portion of the first common power line VSSL1 may be configured to extend from the first common power shorting bar SB1.

As shown in FIG. 21, the first power pad portion 210 may be disposed on the substrate 111, and at least a portion of the first common power line VSSL1 may be configured to extend from the first power pad portion 210. For example, at least a portion of the first power pad portion 210 and the first common power line VSSL1 may be integrally formed on the substrate 111. For example, the first power pad portion 210 may extend in the second direction (or X-axis direction) on the substrate 111, and at least a portion of the first common power line VSSL1 may extend from the first power pad portion 210 in the first direction (or Y-axis direction). The buffer layer BF, the interlayer insulating layer ILD, the first passivation layer PAS1, and the second passivation layer PAS2 may be disposed on the first power pad portion 210 and the first common power line VSSL1. The first common power shorting bar SB1 may be disposed on the interlayer insulating layer ILD and may be connected to at least a portion of the first common power line VSSL1 through a first contact hole CH1 passing through the interlayer insulating layer ILD and the buffer layer BF. For example, at least a portion of the first common power line VSSL1 may cross the first common power shorting bar SB1 and the second common power shorting bar SB2 and may be connected to the first power pad portion 210 and the first common power shorting bar SB1.

As shown in FIG. 22, the second power pad portion 220 may be disposed on the substrate 111, and at least a portion of the second common power line VSSL2 may be configured to extend from the second power pad portion 220. For example, at least a portion of the second power pad portion 220 and the second common power line VSSL2 may be integrally formed on the substrate 111. For example, the second power pad portion 220 may extend in the second direction (or the X-axis direction) on the substrate 111, and at least a portion of the second common power line VSSL2 may extend from the second power pad portion 220 in the first direction (or Y-axis direction). The buffer layer BF, the interlayer insulating layer ILD, the first passivation layer PAS1, and the second passivation layer PAS2 may be disposed on the second power pad portion 220 and the second common power line VSSL2. The second common power shorting bar SB2 may be disposed on the interlayer insulating layer ILD and may be connected to at least a portion of the second common power line VSSL2 through a second contact hole CH2 passing through the interlayer insulating layer ILD and the buffer layer BF. For example, at least a portion of the second common power line VSSL2 may cross the first common power shorting bar SB1 and the second common power shorting bar SB2 and may be connected to the second power pad portion 220 and the second common power shorting bar SB2.

As shown in FIG. 23, at least another portion of the first common power line VSSL1 may be configured to be spaced apart from the second power pad portion 220 on the substrate 111. At least another portion of the first common power line VSSL1 may be disposed to overlap the first common power shorting bar SB1 disposed on the interlayer insulating layer ILD. At least another portion of the first common power line VSSL1 may extend from the position overlapping the first common power shorting bar SB1 in the first direction (or Y-axis direction). For example, at least another portion of the first common power line VSSL1 may be connected to the first common power shorting bar SB1 through a first contact hole CH1 passing through the interlayer insulating layer ILD and the buffer layer BF and may be electrically connected to the first power pad portion 210 through the first common power shorting bar SB1. For example, at least another portion of the first common power line VSSL1 may overlap the first common power shorting bar SB1 and may be connected to the first common power shorting bar SB1.

As shown in FIG. 24, at least another portion of the second common power line VSSL2 may be configured to be spaced apart from the first power pad portion 210 on the substrate 111. At least another portion of the second common power line VSSL2 may be disposed to overlap the second common power shorting bar SB2 disposed on the interlayer insulating layer ILD. At least another portion of the second common power line VSSL2 may be configured to extend in the first direction (or Y-axis direction) from the position overlapping the second common power shorting bar SB2. For example, at least another portion of the second common power line VSSL2 may be connected to the second common power shorting bar SB1 through a second contact hole CH2 passing through the interlayer insulating layer ILD and the buffer layer BF and may be electrically connected to the second power pad portion 220 through the second common power shorting bar SB2. For example, at least another portion of the second common power line VSSL2 may overlap the second common power shorting bar SB2 and may be connected to the second common power shorting bar SB2.

According to another embodiment of the present disclosure, the first and second power pad portions 210 and 220, the first and second common power shorting bars SB1 and SB2, and the first and second common power lines VSSL1 and VSSL2 may be formed of the same material in the same layer, thereby reducing or minimizing the occurrence of step difference in the first and second power pad portions 210 and 220, the first and second common power shorting bars SB1 and SB2, and the first and second common power lines VSSL1 and VSSL2. Accordingly, it is possible to implement or realize the light emitting display apparatus capable of further improving the detection reliability of semi-dark repair target based on the first and second common power voltages applied through the first common power line VSSL1 and the second common power line VSSL2.

FIG. 25 illustrates a region B shown in FIG. 15 according to another embodiment of the present disclosure.

FIG. 25 additionally configures a compensation pattern in the light emitting display apparatus described with reference to FIGS. 20 to 24. Accordingly, in the description of FIG. 25, the remaining components except for the compensation pattern and the configuration related thereto are designated by the same reference numerals, and a redundant description thereof will be omitted or simplified.

Referring to FIG. 25, the display panel 110 of the light emitting display apparatus according to another embodiment of the present disclosure may further include a compensation pattern CP based on the electrical distance difference between the first common power line VSSL1 and the second common power line VSSL2.

The first common power shorting bar SB1 and the second common power shorting bar SB2 may be spaced apart from each other in the first direction (or Y-axis direction). For example, the first common power shorting bar SB1 may be disposed closer to the display area DA than the second common power shorting bar SB2. For example, the second common power shorting bar SB2 may be disposed closer to the pad area PA than the first common power shorting bar SB1. Accordingly, the first common power line VSSL1 connected to the first common power shorting bar SB1 and the second common power line VSSL2 connected to the second common power shorting bar SB2 may have different electrical distances from each other. For example, the second common power line VSSL2 connected to the second common power shorting bar SB2 may have a longer length than the first common power line VSSL1 connected to the first common power shorting bar SB1, and the first common power line VSSL1 may be configured with the compensation pattern CP based on the electrical distance difference with the second common power line VSSL2. For example, the electrical distance difference may be a resistance deviation between the first common power line VSSL1 and the second common power line VSSL2.

The compensation pattern CP may be configured to compensate for the electrical distance difference between the first common power line VSSL1 and the second common power line VSSL2. For example, the compensation pattern CP may be configured to compensate for the resistance deviation between the first common power line VSSL1 and the second common power line VSSL2. For example, the compensation pattern CP may be configured to extend the electrical distance of the first common power line VSSL1. The compensation pattern CP may be configured to extend the electrical distance of the first common power line VSSL1 by the difference between the electrical distance of the first common power line VSSL1 and the electrical distance of the second common power line VSSL2. For example, the compensation pattern CP may be configured in a zigzag shape in a portion of the first common power line VSSL1, but embodiments of the present disclosure are not limited thereto.

According to another embodiment of the present disclosure, the compensation pattern CP is configured to compensate for the resistance deviation between the first common power line VSSL1 and the second common power line VSSL2 divided into the two so that it is possible to implement or realize the light emitting display apparatus capable of further improving the detection reliability of semi-dark repair target based on the first and second common power voltages applied through the first common power line VSSL1 and the second common power line VSSL2.

A light emitting display apparatus according to one or more embodiments of the present disclosure will be described below.

A light emitting display apparatus according to one or more embodiments of the present disclosure may include a light emitting element including a pixel electrode, an emission layer, and a common electrode, a pixel circuit connected to the pixel electrode, a first common power line connected to the common electrode and configured to be applied with a first common power voltage, and a second common power line connected to the common electrode and configured to be applied with a second common power voltage, the pixel electrode may include a first divided pixel electrode and a second divided pixel electrode which are divided from each other, and the first divided pixel electrode and the second divided pixel electrode have different electrical distances with respect to the first common power line and the second common power line.

According to one or more embodiments of the present disclosure, the electrical distance may be a distance over which a resistance, a voltage, or a current is changed.

According to one or more embodiments of the present disclosure, a first electrical distance of the first divided pixel electrode may correspond to a resistance between the common electrode overlapping the first divided pixel electrode and the first common power line, and a second electrical distance of the second divided pixel electrode may correspond to a resistance between the common electrode overlapping the second divided pixel electrode and the second common power line.

According to one or more embodiments of the present disclosure, the first electrical distance may correspond to a resistance between a portion of the common electrode overlapping the first divided pixel electrode and a contact portion of the common electrode connected to the first common power line, and the second electrical distance may correspond to a resistance between a portion of the common electrode overlapping the second divided pixel electrode and a contact portion of the common electrode connected to the second common power line.

According to one or more embodiments of the present disclosure, the pixel circuit may be connected in common to the first divided pixel electrode and the second divided pixel electrode.

According to one or more embodiments of the present disclosure, the first divided pixel electrode and the second divided pixel electrode may be configured to receive the first common power voltage and the second common power voltage from the first common power line and the second common power line through the common electrode.

According to one or more embodiments of the present disclosure, the first common power voltage and the second common power voltage may be configured to be simultaneously applied to the first divided pixel electrode and the second divided pixel electrode.

According to one or more embodiments of the present disclosure, the first common power voltage and the second common power voltage may have a same voltage level or different voltage levels.

According to one or more embodiments of the present disclosure, the first common power voltage may have a lower voltage level than the second common power voltage.

According to one or more embodiments of the present disclosure, the first common power voltage and the second common power voltage may have a same voltage level in a normal driving state, and have different voltage levels in a semi-dark repair process.

According to one or more embodiments of the present disclosure, may further include a connection line connected between at least one of the first divided pixel electrode or the second divided pixel electrode and the pixel circuit.

According to one or more embodiments of the present disclosure, the connection line may electrically connect at least one of the first divided pixel electrode or the second divided pixel electrode to the pixel circuit.

According to one or more embodiments of the present disclosure, any one of the first divided pixel electrode or the second divided pixel electrode may be electrically separated from the connection line, and another one of the first divided pixel electrode or the second divided pixel electrode may be electrically connected to the pixel circuit through the connection line.

According to one or more embodiments of the present disclosure, the first common power line and the second common power line may extend parallel to each other in a first direction, and the first divided pixel electrode and the second divided pixel electrode may be disposed adjacent to each other in the first direction or adjacent to each other in a second direction which intersects the first direction.

According to one or more embodiments of the present disclosure, may further include a plurality of subpixels including an emission area in which the light emitting element and the pixel circuit are disposed, the plurality of subpixels may be arranged in the first direction, may not overlap with the first common power line and the second common power line, or may overlap with at least one of the first common power line and the second common power line.

According to one or more embodiments of the present disclosure, the first common power line and the second common power line may be disposed adjacent to each other at one side or another side in the second direction of the plurality of subpixels.

According to one or more embodiments of the present disclosure, the first common power line may be disposed at one side in the second direction of the plurality of subpixels, and the second common power line may be disposed at another side in the second direction of the plurality of subpixels.

According to one or more embodiments of the present disclosure, the first common power line and the second common power line may be electrically connected to the common electrode, respectively, at different positions in the first direction.

According to one or more embodiments of the present disclosure, the first common power line and the second common power line may be electrically connected to the common electrode at a same position or different positions in the first direction, and the first divided pixel electrode and the second divided pixel electrode may have different electrical distances with respect to a contact portion of the first common power line and a contact portion of the second common power line.

According to one or more embodiments of the present disclosure, the first divided pixel electrode and the second divided pixel electrode may be disposed adjacent to each other in the second direction, the first common power line may be disposed adjacent to the first divided pixel electrode at one side in the second direction of the plurality of subpixels, and the second common power line may be disposed adjacent to the second divided pixel electrode at the other side in the second direction of the plurality of subpixels.

According to one or more embodiments of the present disclosure, each of the plurality of subpixels may further include a transmission area adjacent to the emission area in the second direction, and at least one of the first common power line and the second common power line may overlap the transmission area.

According to one or more embodiments of the present disclosure, one of the first common power line or the second common power line may be disposed to overlap the emission area, and another one of the first common power line or the second common power line may be disposed to overlap the transmission area.

According to one or more embodiments of the present disclosure, the transmission area may further include an undercut structure surrounding an edge of the transmission area, and the first common power line and the second common power line may not overlap with the undercut structure.

According to one or more embodiments of the present disclosure, the undercut structure may disconnect the common electrode disposed in the transmission area from the common electrode disposed in the emission area.

According to one or more embodiments of the present disclosure, the common electrode may overlap both of the first divided pixel electrode and the second divided pixel electrode.

According to one or more embodiments of the present disclosure, the first common power line may be configured to apply the first common power voltage to each of the first divided pixel electrode and the second divided pixel electrode through the common electrode, and the second common power line may be configured to apply the second common power voltage to each of the first divided pixel electrode and the second divided pixel electrode through the common electrode.

According to one or more embodiments of the present disclosure, the common electrode may include a first common electrode and a second common electrode separated to correspond to the first divided pixel electrode and the second divided pixel electrode, respectively.

According to one or more embodiments of the present disclosure, the first common power line may be configured to apply the first common power voltage to the first divided pixel electrode through the first common electrode, and the second common power line may be configured to apply the second common power voltage to the second divided pixel electrode through the second common electrode.

According to one or more embodiments of the present disclosure, may further include a substrate including a display area in which a plurality of subpixels including the emission area in which the light emitting element and the pixel circuit are disposed and a non-display area in the periphery of the display area, the first common power line and the second common power line may extend parallel to each other in a first direction in the display area, and at least one common power shorting bar may extend in a second direction intersecting the first direction in the non-display area and is connected to the first common power line and the second common power line.

According to one or more embodiments of the present disclosure, the at least one common power shorting bar may include a first common power shorting bar connected to the first common power line, and a second common power shorting bar connected to the second common power line and spaced apart from the first common power shorting bar, the first common power shorting bar may be disposed closer to the display area than the second common power shorting bar.

According to one or more embodiments of the present disclosure, the first common power shorting bar and the second common power shorting bar may be disposed at a same layer or different layers on the substrate.

According to one or more embodiments of the present disclosure, the first common power line may include a compensation pattern based on the electrical distance difference with the second common power line.

According to one or more embodiments of the present disclosure, the compensation pattern may extend the electrical distance of the first common power line.

According to one or more embodiments of the present disclosure, the compensation pattern may include a zigzag shape.

According to one or more embodiments of the present disclosure, the first common power line and the second common power line may be disposed at different layers on the substrate, and the second common power line may intersect and overlap the first common power shorting bar.

According to one or more embodiments of the present disclosure, the first common power line and the second common power line may be disposed at a same layer on the substrate, and the first common power shorting bar and the second common power shorting bar may be disposed at a same layer on the substrate and are disposed at a different layer from the first common power line and the second common power line on the substrate.

According to one or more embodiments of the present disclosure, at least a portion of the first common power line may intersect and overlap the first common power shorting bar, and may be electrically connected to the first common power shorting bar through a first contact hole, and at least another portion of the first common power line may intersect and overlap the first common power shorting bar and the second common power shorting bar and may be electrically connected to the first common power shorting bar through the first contact hole.

According to one or more embodiments of the present disclosure, the at least a portion of the first common power line may do not overlap the second common power shorting bar.

According to one or more embodiments of the present disclosure, the second common power line may intersect and overlap the first common power shorting bar and the second common power shorting bar and may be electrically connected to the second common power shorting bar through a second contact hole.

According to one or more embodiments of the present disclosure, may further include a power pad portion disposed in the non-display area and configured to apply the first common power voltage and the second common power voltage to the at least one common power shorting bar.

According to one or more embodiments of the present disclosure, the power pad portion may include a first power pad portion configured to connect a first common power voltage pad to which the first common power voltage is configured to be applied and the first common power shorting bar, and a second power pad portion configured to connect a second common power voltage pad to which the second common power voltage is configured to be applied and the second common power shorting bar.

According to one or more embodiments of the present disclosure, the first power pad portion and the second power pad portion may be disposed at different layers on the substrate, the first power pad portion crosses the second common power shorting bar and may be connected to the first common power shorting bar, and the second power pad portion may be connected to the second common power shorting bar.

According to one or more embodiments of the present disclosure, the first power pad portion and the second power pad portion may include a straight-line shape in which adjacent sides are parallel to each other, and at least some portions of opposite sides of the first power pad portion and the second power pad portion may be inclined.

According to one or more embodiments of the present disclosure, the first power pad portion and the second power pad portion may be disposed at a same layer on the substrate, at least a portion of the first common power line may cross the first common power shorting bar and the second common power shorting bar and may be connected to the first power pad portion and the first common power shorting bar, and at least a portion of the second common power line may cross the first common power shorting bar and the second common power shorting bar and may be connected to the second power pad portion and the second common power shorting bar.

According to one or more embodiments of the present disclosure, the at least a portion of the first common power line and the first power pad portion may be integrally formed, and the at least a portion of the second common power line and the second power pad portion may be integrally formed.

According to one or more embodiments of the present disclosure, may further include a repair detecting part electrically connected to a common node between the first divided pixel electrode and the second divided pixel electrode.

According to one or more embodiments of the present disclosure, the repair detecting part may be configured to detect a short circuit between one of the first divided pixel electrode or the second divided pixel electrode and the common electrode based on a voltage measurement value of the common node.

According to one or more embodiments of the present disclosure, the repair detecting part may be configured to simultaneously apply the first and second common power voltages having different voltage levels to the first and second common power lines, respectively, and the repair detecting part may be configured to detect a short circuit between one of the first and second divided pixel electrodes and the common electrode based on the voltage measurement value of the common node changed by the first and second common power voltages.

According to one or more embodiments of the present disclosure, the pixel circuit may include a driving transistor including a gate electrode connected to a first node, and a first electrode connected to a second node corresponding to the common node and a second electrode connected to a third node applied with a pixel voltage, and configured to generate a driving current according to a gate-to-source voltage, a first switching transistor connected between a data line of a data voltage and the first node, and a second switching transistor connected between a reference line connected to the repair detecting part and the second node.

According to one or more embodiments of the present disclosure, the repair detecting part may be configured to measure the voltage of the second node and detects whether there is a short circuit between any one of the first divided pixel electrode or the second divided pixel electrode and the common electrode under the condition that the driving transistor and the first switching transistor are turned-off and the second switching transistor is turned-on.

According to one or more embodiments of the present disclosure, the repair detecting part may be configured to detect a short circuit between one of the first divided pixel electrode or the second divided pixel electrode and the common electrode based on the voltage measurement value of the second node changed by applying the first and second common power voltages having different voltage levels through the first and second common power lines.

It will be apparent to those skilled in the art that various modifications and variations may be made in the apparatus of the present disclosure without departing from the scope of the disclosure. Thus, it is intended that the present disclosure cover the modifications and variations of this disclosure including those of the claims and their equivalents.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A light emitting display apparatus comprising:
a light emitting element including a pixel electrode, an emission layer, and a common electrode;
a pixel circuit connected to the pixel electrode;
a first common power line connected to the common electrode and configured to be applied with a first common power voltage; and
a second common power line connected to the common electrode and configured to be applied with a second common power voltage,
wherein the pixel electrode includes a first divided pixel electrode and a second divided pixel electrode, which are divided from each other, and the first divided pixel electrode and the second divided pixel electrode have different electrical distances with respect to the first common power line and the second common power line.

2. The light emitting display apparatus according to claim 1, wherein the electrical distance is a distance over which a resistance, a voltage, or a current is changed.

3. The light emitting display apparatus according to claim 1,
wherein a first electrical distance of the first divided pixel electrode corresponds to a resistance between the common electrode overlapping the first divided pixel electrode and the first common power line, and
wherein a second electrical distance of the second divided pixel electrode corresponds to a resistance between the common electrode overlapping the second divided pixel electrode and the second common power line.

4. The light emitting display apparatus according to claim 3,
wherein the first electrical distance corresponds to a resistance between a portion of the common electrode overlapping the first divided pixel electrode and a contact portion of the common electrode connected to the first common power line, and
wherein the second electrical distance corresponds to a resistance between a portion of the common electrode overlapping the second divided pixel electrode and a contact portion of the common electrode connected to the second common power line.

5. The light emitting display apparatus according to claim 1, wherein the pixel circuit is connected in common to the first divided pixel electrode and the second divided pixel electrode.

6. The light emitting display apparatus according to claim 1,
wherein the first divided pixel electrode and the second divided pixel electrode are configured to receive the first common power voltage and the second common power voltage from the first common power line and the second common power line through the common electrode.

7. The light emitting display apparatus according to claim 6,
wherein the first common power voltage and the second common power voltage are configured to be simultaneously applied to the first divided pixel electrode and the second divided pixel electrode.

8. The light emitting display apparatus according to claim 1,
wherein the first common power voltage and the second common power voltage have a same voltage level or different voltage levels.

9. The light emitting display apparatus according to claim 8,
wherein the first common power voltage has a lower voltage level than the second common power voltage.

10. The light emitting display apparatus according to claim 8, wherein the first common power voltage and the second common power voltage have the same voltage level in a normal driving state, and have different voltage levels in a semi-dark repair process.

11. The light emitting display apparatus according to claim 1, further comprising a connection line connected between at least one of the first divided pixel electrode or the second divided pixel electrode and the pixel circuit.

12. The light emitting display apparatus according to claim 11,
wherein the connection line electrically connects at least one of the first divided pixel electrode or the second divided pixel electrode to the pixel circuit.

13. The light emitting display apparatus according to claim 12,
wherein any one of the first divided pixel electrode or the second divided pixel electrode is electrically separated from the connection line, and
wherein another one of the first divided pixel electrode or the second divided pixel electrode is electrically connected to the pixel circuit through the connection line.

14. The light emitting display apparatus according to claim 1,
wherein the first common power line and the second common power line extend parallel to each other in a first direction, and
wherein the first divided pixel electrode and the second divided pixel electrode are disposed adjacent to each other in the first direction or adjacent to each other in a second direction which intersects the first direction.

15. The light emitting display apparatus according to claim 14, further comprising a plurality of subpixels including an emission area in which the light emitting element and the pixel circuit are disposed,
wherein the plurality of subpixels are arranged in the first direction, are not overlapped with the first common power line and the second common power line, or are overlapped with at least one of the first common power line and the second common power line.

16. The light emitting display apparatus according to claim 15,
wherein the first common power line and the second common power line are disposed adjacent to each other at one side or another side in the second direction of the plurality of subpixels.

17. The light emitting display apparatus according to claim 15,
wherein the first common power line is disposed at one side in the second direction of the plurality of subpixels, and
wherein the second common power line is disposed at another side in the second direction of the plurality of subpixels.

18. The light emitting display apparatus according to claim 15,
wherein the first common power line and the second common power line are electrically connected to the common electrode, respectively, at different positions in the first direction.

19. The light emitting display apparatus according to claim 15,
wherein the first common power line and the second common power line are electrically connected to the common electrode at a same position or different positions in the first direction, and
wherein the first divided pixel electrode and the second divided pixel electrode have different electrical distances with respect to a contact portion of the first common power line and a contact portion of the second common power line.

20. The light emitting display apparatus according to claim 19,
wherein the first divided pixel electrode and the second divided pixel electrode are disposed adjacent to each other in the second direction,
wherein the first common power line is disposed adjacent to the first divided pixel electrode at one side in the second direction of the plurality of subpixels, and
wherein the second common power line is disposed adjacent to the second divided pixel electrode at the other side in the second direction of the plurality of subpixels.

21. The light emitting display apparatus according to claim 15,
wherein each of the plurality of subpixels further includes a transmission area adjacent to the emission area in the second direction, and
wherein at least one of the first common power line and the second common power line overlaps the transmission area.

22. The light emitting display apparatus according to claim 21,
wherein one of the first common power line or the second common power line is disposed to overlap the emission area, and
wherein another one of the first common power line or the second common power line is disposed to overlap the transmission area.

23. The light emitting display apparatus according to claim 21,
wherein the transmission area further includes an undercut structure surrounding an edge of the transmission area, and
wherein the first common power line and the second common power line are not overlapped with the undercut structure.

24. The light emitting display apparatus according to claim 23,
wherein the undercut structure disconnects the common electrode disposed in the transmission area from the common electrode disposed in the emission area.

25. The light emitting display apparatus according to claim 1,
wherein the common electrode overlaps both of the first divided pixel electrode and the second divided pixel electrode.

26. The light emitting display apparatus according to claim 25,
wherein the first common power line is configured to apply the first common power voltage to each of the first divided pixel electrode and the second divided pixel electrode through the common electrode, and
wherein the second common power line is configured to apply the second common power voltage to each of the first divided pixel electrode and the second divided pixel electrode through the common electrode.

27. The light emitting display apparatus according to claim 1,
wherein the common electrode includes a first common electrode and a second common electrode separated to correspond to the first divided pixel electrode and the second divided pixel electrode, respectively.

28. The light emitting display apparatus according to claim 27,
wherein the first common power line is configured to apply the first common power voltage to the first divided pixel electrode through the first common electrode, and
wherein the second common power line is configured to apply the second common power voltage to the second divided pixel electrode through the second common electrode.

29. The light emitting display apparatus according to claim 1, further comprising a substrate including a display area in which a plurality of subpixels including the emission area in which the light emitting element and the pixel circuit are disposed and a non-display area in the periphery of the display area,
wherein the first common power line and the second common power line extend parallel to each other in a first direction in the display area, and
wherein at least one common power shorting bar extends in a second direction intersecting the first direction in the non-display area and is connected to the first common power line and the second common power line.

30. The light emitting display apparatus according to claim 29, wherein the at least one common power shorting bar includes:
a first common power shorting bar connected to the first common power line; and
a second common power shorting bar connected to the second common power line and spaced apart from the first common power shorting bar,
wherein the first common power shorting bar is disposed closer to the display area than the second common power shorting bar.

31. The light emitting display apparatus according to claim 30, wherein the first common power shorting bar and the second common power shorting bar are disposed at a same layer or different layers on the substrate.

32. The light emitting display apparatus according to claim 30, wherein the first common power line includes a compensation pattern based on the electrical distance difference with the second common power line.

33. The light emitting display apparatus according to claim 32, wherein the compensation pattern extends the electrical distance of the first common power line.

34. The light emitting display apparatus according to claim 32, wherein the compensation pattern includes a zigzag shape.

35. The light emitting display apparatus according to claim 30,
wherein the first common power line and the second common power line are disposed at different layers on the substrate, and
wherein the second common power line intersects and overlaps the first common power shorting bar.

36. The light emitting display apparatus according to claim 29,
wherein the first common power line and the second common power line are disposed at a same layer on the substrate, and
wherein the first common power shorting bar and the second common power shorting bar are disposed at a same layer on the substrate and are disposed at a different layer from the first common power line and the second common power line on the substrate.

37. The light emitting display apparatus according to claim 36,
wherein at least a portion of the first common power line intersects and overlaps the first common power shorting bar, and is electrically connected to the first common power shorting bar through a first contact hole, and
wherein at least another portion of the first common power line intersects and overlaps the first common power shorting bar and the second common power shorting bar and is electrically connected to the first common power shorting bar through the first contact hole.

38. The light emitting display apparatus according to claim 37,
wherein the at least a portion of the first common power line does not overlap the second common power shorting bar.

39. The light emitting display apparatus according to claim 36,
wherein the second common power line intersects and overlaps the first common power shorting bar and the second common power shorting bar and is electrically connected to the second common power shorting bar through a second contact hole.

40. The light emitting display apparatus according to claim 30, further comprising a power pad portion disposed in the non-display area and configured to apply the first common power voltage and the second common power voltage to the at least one common power shorting bar.

41. The light emitting display apparatus according to claim 40,
wherein the power pad portion includes:
a first power pad portion configured to connect a first common power voltage pad to which the first common power voltage is configured to be applied and the first common power shorting bar; and
a second power pad portion configured to connect a second common power voltage pad to which the second common power voltage is configured to be applied and the second common power shorting bar.

42. The light emitting display apparatus according to claim 41,
wherein the first power pad portion and the second power pad portion are disposed at different layers on the substrate,
wherein the first power pad portion crosses the second common power shorting bar and is connected to the first common power shorting bar, and
wherein the second power pad portion is connected to the second common power shorting bar.

43. The light emitting display apparatus according to claim 42,
wherein the first power pad portion and the second power pad portion include a straight-line shape in which adjacent sides are parallel to each other, and wherein at least some portions of opposite sides of the first power pad portion and the second power pad portion are inclined.

44. The light emitting display apparatus according to claim 41,
wherein the first power pad portion and the second power pad portion are disposed at a same layer on the substrate,
wherein at least a portion of the first common power line crosses the first common power shorting bar and the second common power shorting bar and is connected to the first power pad portion and the first common power shorting bar, and
wherein at least a portion of the second common power line crosses the first common power shorting bar and the second common power shorting bar and is connected to the second power pad portion and the second common power shorting bar.

45. The light emitting display apparatus according to claim 44, wherein the at least a portion of the first common power line and the first power pad portion are integrally formed, and
wherein the at least a portion of the second common power line and the second power pad portion are integrally formed.

46. The light emitting display apparatus according to claim 1, further comprising a repair detecting part electrically connected to a common node between the first divided pixel electrode and the second divided pixel electrode.

47. The light emitting display apparatus according to claim 46, wherein the repair detecting part is configured to detect a short circuit between one of the first divided pixel electrode or the second divided pixel electrode and the common electrode based on a voltage measurement value of the common node.

48. The light emitting display apparatus according to claim 47,
wherein the repair detecting part is configured to simultaneously apply the first and second common power voltages having different voltage levels to the first and second common power lines, respectively, and
wherein the repair detecting part is configured to detect a short circuit between one of the first and second divided pixel electrodes and the common electrode based on the voltage measurement value of the common node changed by the first and second common power voltages.

49. The light emitting display apparatus according to claim 46,
wherein the pixel circuit includes:
a driving transistor including a gate electrode connected to a first node, a first electrode connected to a second node corresponding to the common node and a second electrode connected to a third node applied with a pixel voltage, and configured to generate a driving current according to a gate-to-source voltage;
a first switching transistor connected between a data line of a data voltage and the first node; and
a second switching transistor connected between a reference line connected to the repair detecting part and the second node.

50. The light emitting display apparatus according to claim 49, wherein the repair detecting part is configured to measure the voltage of the second node and detect whether there is a short circuit between any one of the first divided pixel electrode or the second divided pixel electrode and the common electrode under the condition that the driving transistor and the first switching transistor are turned-off and the second switching transistor is turned-on.

51. The light emitting display apparatus according to claim 50, wherein the repair detecting part is configured to detect a short circuit between one of the first divided pixel electrode or the second divided pixel electrode and the common electrode based on the voltage measurement value of the second node changed by applying the first and second common power voltages having different voltage levels through the first and second common power lines.
